(19) United States
(12) Patent Application Publication
(10) Pub. No.: US 2026/0247956 A1
(43) Pub. Date: Aug. 20, 2026

(54) INTEGRATED CIRCUIT AND MANUFACTURING METHOD THEREOF

(71) Applicant: Taiwan Semiconductor Manufacturing Company, Ltd., Hsinchu (TW)

(72) Inventors: Kuo-Chiang Ting, Hsinchu City (TW); Sung-Feng Yeh, Taipei City (TW); Wei-Lun Hsu, Hsinchu City (TW)

(73) Assignee: Taiwan Semiconductor Manufacturing Company, Ltd., Hsinchu (TW)

(21) Appl. No.: 19/056,789

(22) Filed: Feb. 19, 2025

(51) Int. Cl. H01L 23/522; H01L 23/00; H01L 23/48; H01L 25/07; H10D 1/00; H10D 1/68

(52) U.S. Cl. CPC H10W 20/496; H10D 1/042; H10W 20/20; H10W 90/00; H10D 1/714; H10D 1/716; H10W 70/09; H10W 70/60; H10W 70/6528; H10W 90/792

(57) ABSTRACT

An integrated circuit includes a carrier, a first die, a second die, a redistribution structure, and a first capacitor. The first die is disposed on the carrier. The second die is disposed on and bonded to the first die. The redistribution structure is disposed on the second die. The first die and the redistribution structure are located on two opposite sides of the second die. The first capacitor structure is embedded in the redistribution structure.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1J are schematic cross-sectional views illustrating a manufacturing process of an integrated circuit in accordance with some embodiments of the disclosure.

FIG. 2A to FIG. 2G are enlarged views of a region in FIG. 1J to illustrate a manufacturing process of the capacitor structure, the conductive pads, the passivation layer, and the UBM patterns.

FIG. 3A to FIG. 3C are schematic cross-sectional views illustrating a manufacturing process of an integrated circuit in accordance with some alternative embodiments of the disclosure.

FIG. 4A to FIG. 4G are enlarged views of a region in FIG. 3B to illustrate a manufacturing process of the capacitor structure, the protection layer, the conductive patterns, and the dielectric layers.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

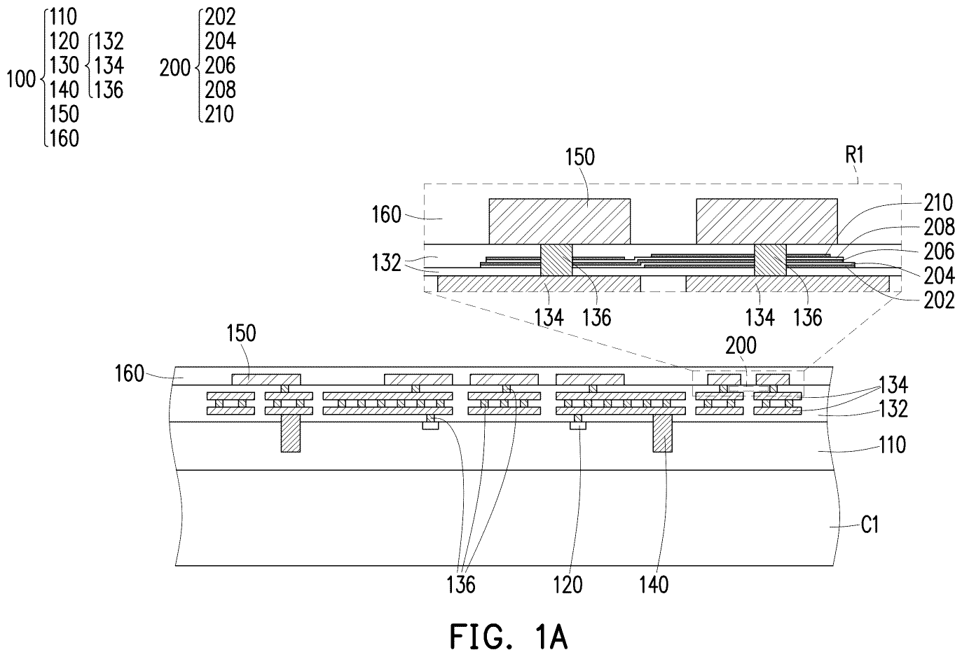

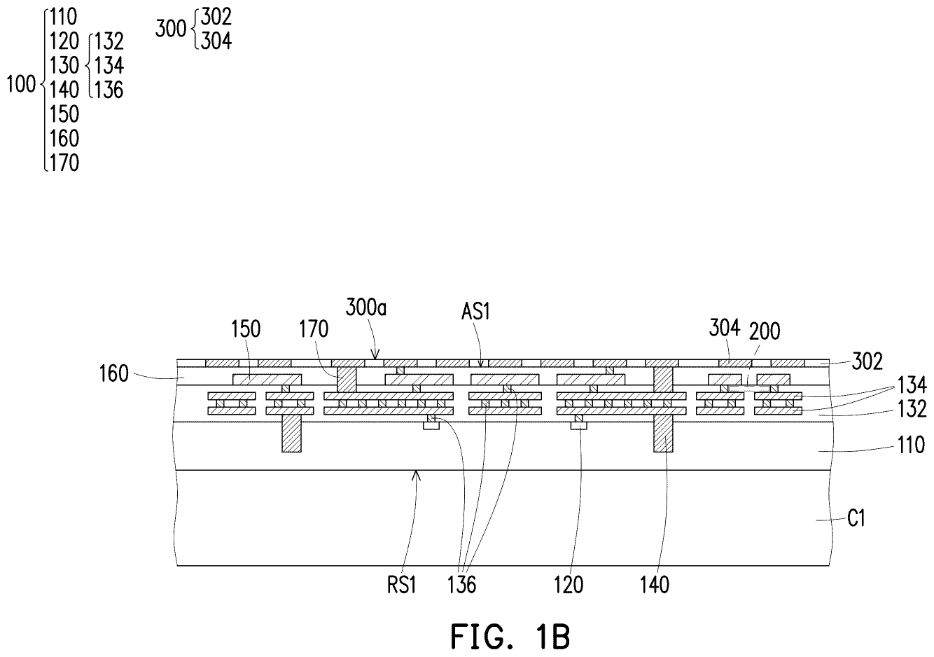

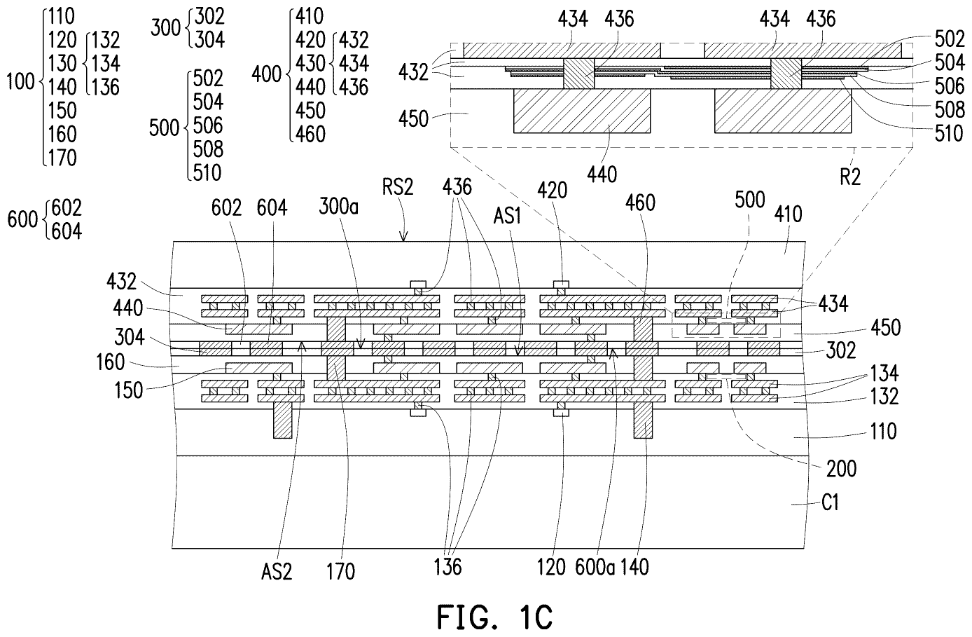

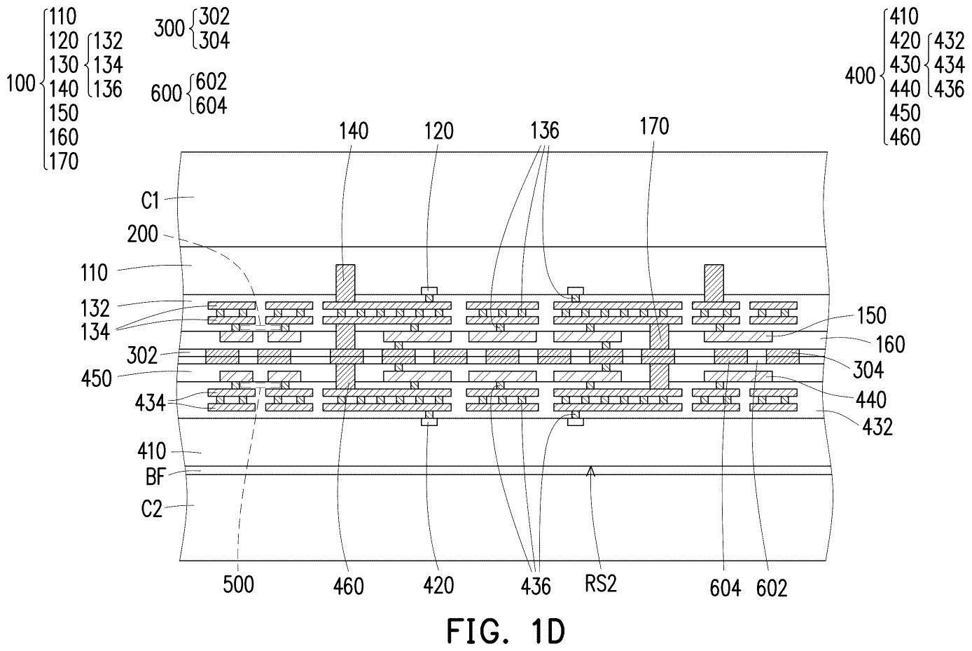

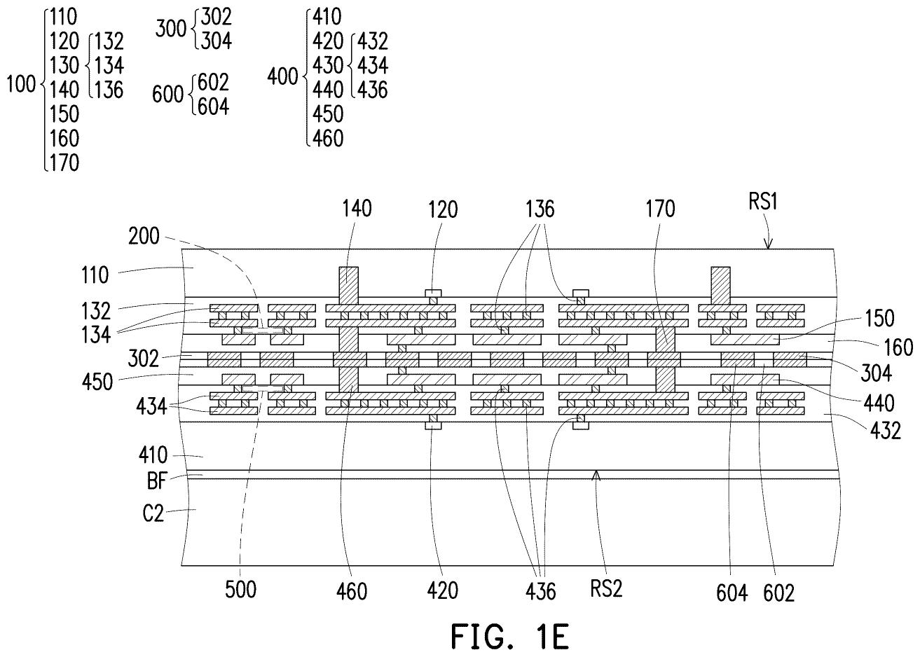

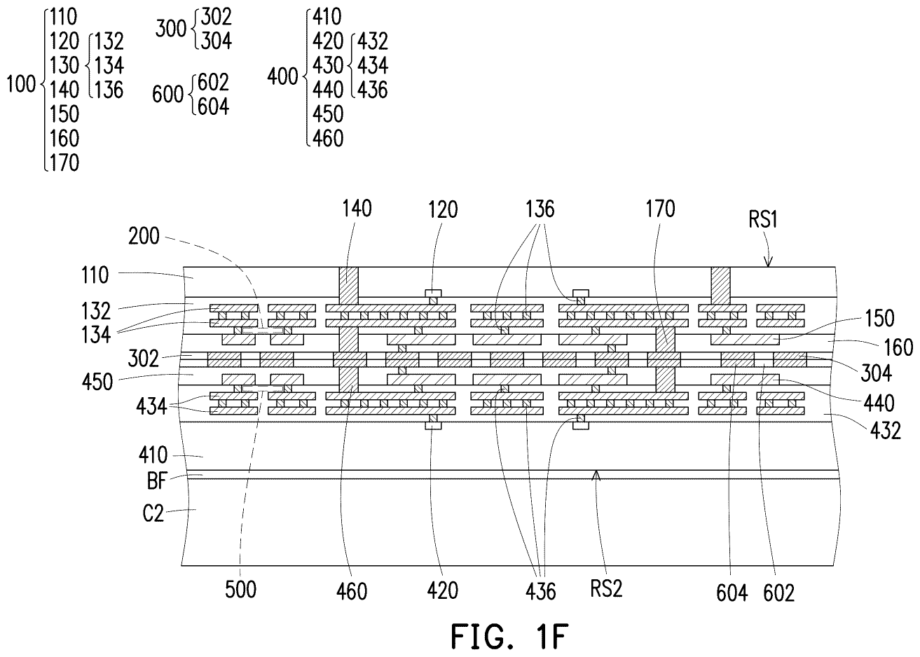

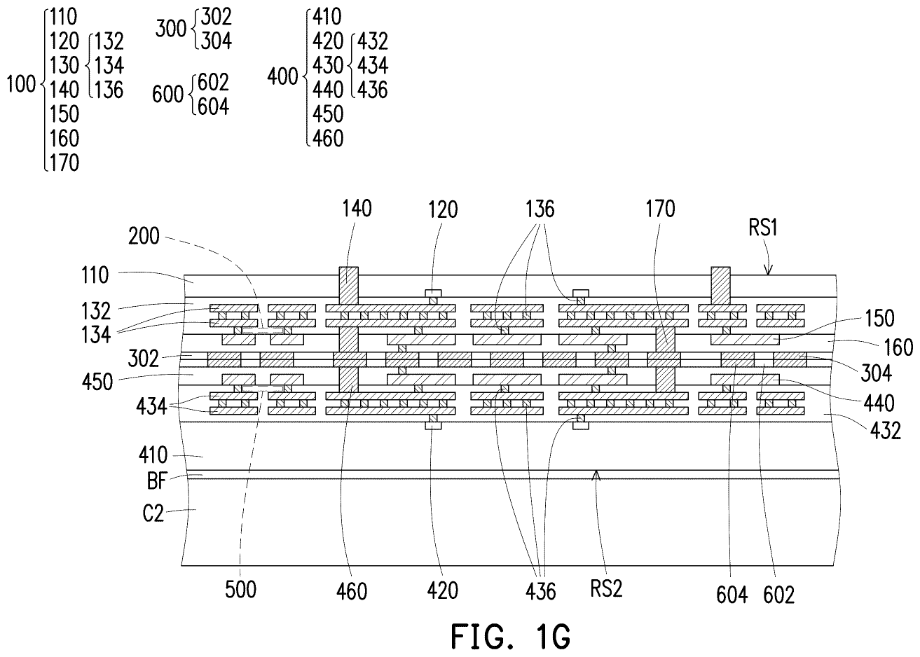

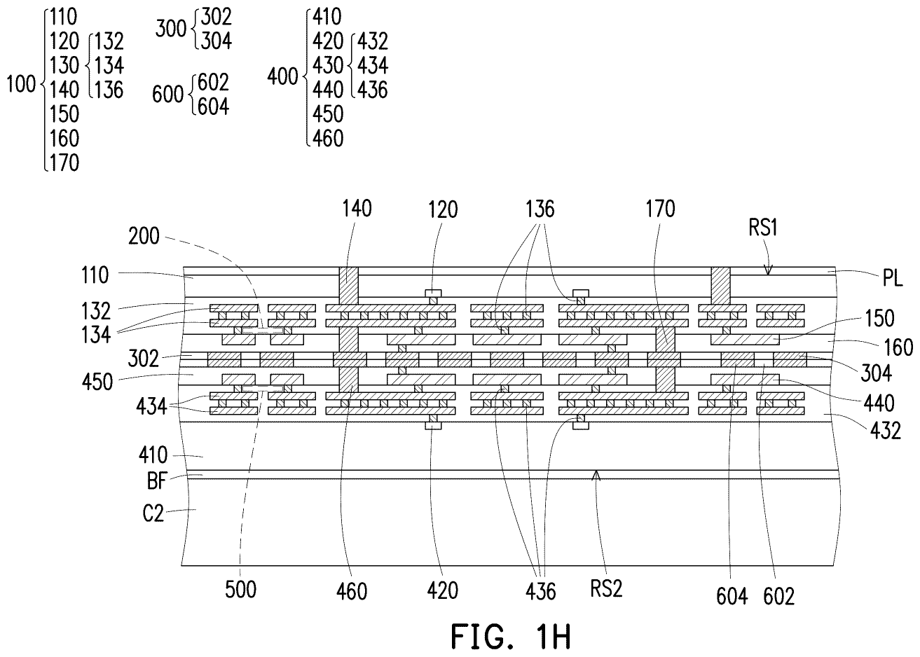

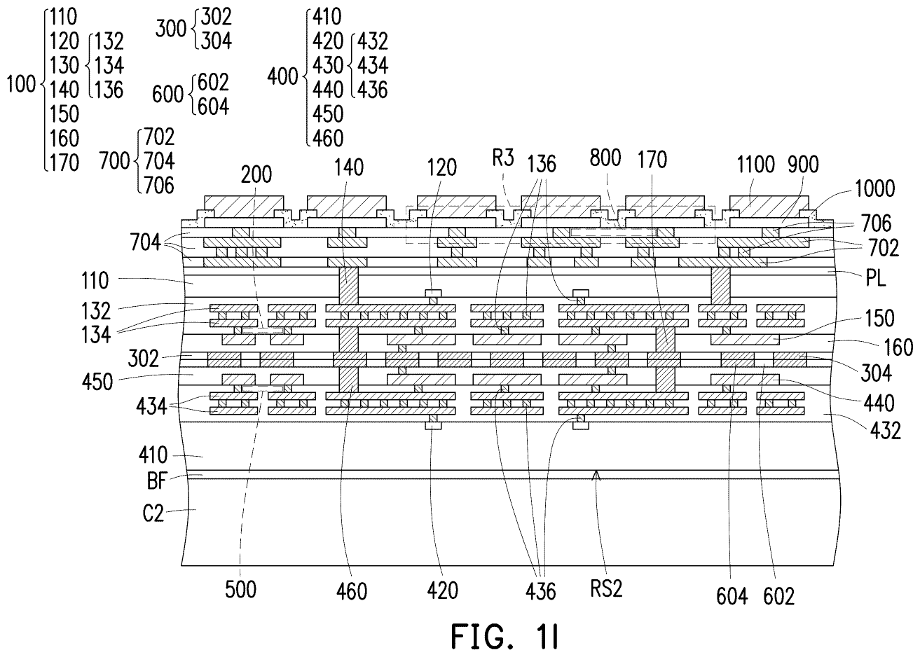

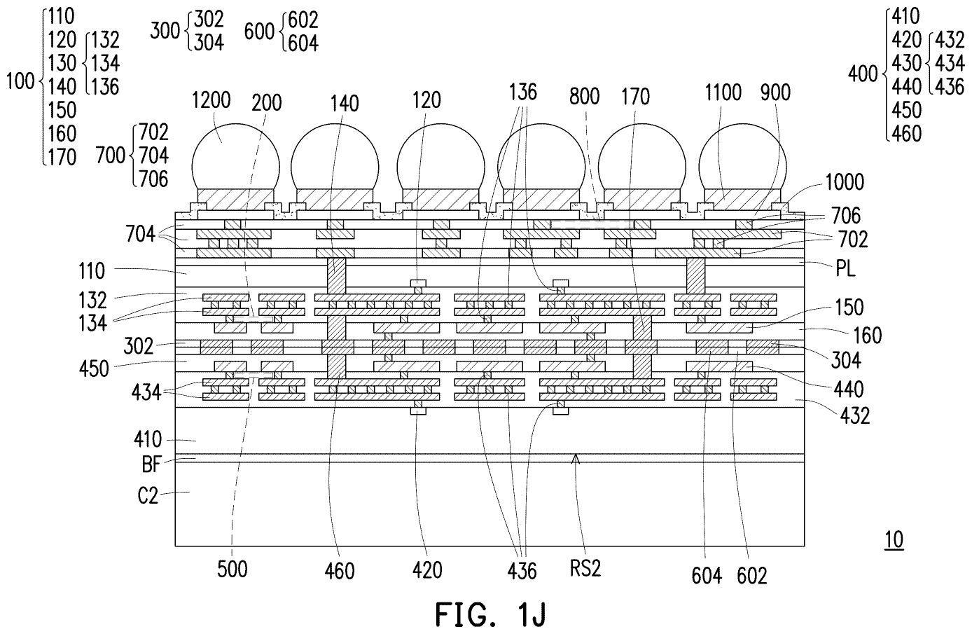

FIG. 1A to FIG. 1J are schematic cross-sectional views illustrating a manufacturing process of an integrated circuit 10 in accordance with some embodiments of the disclosure. Referring to FIG. 1A, a carrier C1 is provided. In some embodiments, the carrier C1 is made of silicon, polymer, polymer composite, metal foil, ceramic, glass, glass epoxy, tape, or other suitable material for structural support. In some embodiments, the carrier C1 is free of active components and passive components. In some embodiments, the carrier C1 is also free of wire routings. For example, the carrier C1 may be a blank substrate which purely functions as a supporting element without serving any signal transmission function.

As illustrated in FIG. 1A, a die 100 is placed on the carrier C1. In some embodiments, the die 100 includes a semiconductor substrate 110, a plurality of devices 120, an interconnect structure 130, a plurality of through semiconductor vias (TSV) 140, a plurality of conductive pads 150, and a passivation layer 160. The semiconductor substrate 110 may be made of elemental semiconductor materials, such as crystalline silicon, diamond, or germanium; compound semiconductor materials, such as silicon carbide, gallium arsenic, indium arsenide, or indium phosphide; or alloy semiconductor materials, such as silicon germanium, silicon germanium carbide, gallium arsenic phosphide, or gallium indium phosphide. The semiconductor substrate 110 may be a bulk silicon substrate, a silicon-on-insulator (SOI) substrate, or a germanium-on-insulator (GOI) substrate. In some embodiments, the devices 120 are formed in the semiconductor substrate 110. The devices 120 may include active components (e.g., transistors or the like) and/or passive components (e.g., resistors, capacitors, inductors, or the like).

As illustrated in FIG. 1A, an interconnect structure 130 is formed on the semiconductor substrate 110. In some embodiments, the interconnect structure 130 includes a dielectric layer 132, a plurality of conductive patterns 134, and a plurality of conductive vias 136. For simplicity, the dielectric layer 132 is illustrated as a single dielectric layer and the conductive patterns 134 are illustrated as embedded in the dielectric layer 132. Nevertheless, from the perspective of the manufacturing process, the dielectric layer 132 is constituted by at least two dielectric layers, and the conductive patterns 134 are sandwiched between two adjacent dielectric layers. In some embodiments, the conductive patterns 134 located at different level heights are connected to each other through the conductive vias 136. In other words, the conductive patterns 134 are electrically connected to each other through the conductive vias 136. In some embodiments, the bottommost conductive vias 136 are connected to the devices 120 embedded in the semiconductor substrate 110. In other words, the bottommost conductive vias 136 establish electrical connection between the devices 120 and the conductive patterns 134 of the interconnect structure 130. In some embodiments, the bottommost conductive vias 136 are referred to as “contact structures” of the devices 120.

In some embodiments, a material of the dielectric layer 132 includes polyimide, epoxy resin, acrylic resin, phenol resin, benzocyclobutene (BCB), polybenzooxazole (PBO), or any other suitable polymer-based dielectric material. The dielectric layer 132, for example, may be formed by suitable fabrication techniques such as spin-on coating, chemical vapor deposition (CVD), plasma-enhanced chemical vapor deposition (PECVD), or the like. In some embodiments, materials of the conductive patterns 134 and the conductive vias 136 include aluminum, titanium, copper, nickel, tungsten, or alloys thereof. The conductive patterns 134 and the conductive vias 136 may be formed by, for example, electroplating, deposition, and/or photolithography and etching. In some embodiments, the conductive patterns 134 and the underlying conductive vias 136 are formed simultaneously. It should be noted that the number of the dielectric layers 132, the number of the conductive patterns 134, and the number of the conductive vias 136 illustrated in FIG. 1A are merely for illustrative purposes, and the disclosure is not limited thereto. In some alternative embodiments, fewer or more layers of the dielectric layers 132, the conductive patterns 134, or the conductive vias 136 may be formed depending on the circuit design.

In some embodiments, the TSVs 140 are embedded in the semiconductor substrate 110 and the dielectric layer 132 of the interconnect structure 130. That is, the TSVs 140 extend from the semiconductor substrate 110 to the interconnect structure 130. For example, a portion of each TSV 140 is embedded in the semiconductor substrate 110 while another portion of the same TSV 140 is embedded in the dielectric layer 132 of the interconnect structure 130. In some embodiments, the TSVs 140 are directly in contact with the conductive pattern 134 to render electrical connection with the interconnect structure 130.

As illustrated in FIG. 1A, the conductive pads 150 are formed over the interconnect structure 130. In some embodiments, the conductive pads 150 are electrically connected to the conductive patterns 134 of the interconnect structure 130 through the topmost conductive vias 136. In some embodiments, the conductive pads 150 are used to establish electrical connection with other components (not shown) or dies (not shown) subsequently formed or provided. In some alternative embodiments, the conductive pads 150 may be test pads. In some embodiments, the conductive pads 150 are aluminum pads, copper pads, or other suitable metal pads.

In some embodiments, the passivation layer 160 is formed over the interconnect structure 130 and the conductive pads 150. In some embodiments, a material of the passivation layer 160 includes oxides, such as silicon oxide or the like. Alternatively, the passivation layer 160 may include polyimide, epoxy resin, acrylic resin, phenol resin, BCB, PBO, or any other suitable polymer-based dielectric material. The passivation layer 160 may be formed by suitable fabrication techniques, such as spin-on coating, CVD, PECVD, or the like.

As illustrated in FIG. 1A, a capacitor structure 200 is formed to be embedded in the interconnect structure 130. For example, the capacitor structure 200 is embedded in the dielectric layer 132 of the interconnect structure 130. In some embodiments, the capacitor structure 200 includes an electrode 202, a storage layer 204, an electrode 206, a storage layer 208, and an electrode 210. In some embodiments, the capacitor structure 200 is formed by the following steps. First, a first electrode material layer (not shown) is conformally formed on a top surface of one of the dielectric layers 132 by a suitable technique such as a physical vapor deposition (PVD) process or a plating process. Thereafter, the first electrode material layer is patterned by a photolithography and etching process to form the electrode 202. After the electrode 202 is formed on one of the dielectric layers 132, a first storage material layer (not shown) is conformally formed on the electrode 202 and one of the dielectric layers 132 by a suitable technique such as CVD, PECVD, flowable chemical vapor deposition (FCVD), high-density-plasma chemical vapor deposition (HDP-CVD), sub-atmospheric chemical vapor deposition (SACVD), PVD, or atomic layer deposition (ALD). Thereafter, the first storage material layer is patterned by a photolithography and etching process to form the storage layer 204. The storage layer 204 covers the electrode 202 and one of the dielectric layers 132. Then, a second electrode material layer (not shown) is conformally formed on a top surface of the storage layer 204 by a suitable technique such as a PVD process or a plating process. Thereafter, the second electrode material layer is patterned by a photolithography and etching process to form the electrode 206. After the electrode 206 is formed on the storage layer 204, a second storage material layer (not shown) is conformally formed on the electrode 206 by a suitable technique such as CVD, PECVD, FCVD, HDP-CVD, SACVD, PVD, or ALD. Thereafter, the second storage material layer is patterned by a photolithography and etching process to form the storage layer 208. Subsequently, a third electrode material layer (not shown) is conformally formed on a top surface of the storage layer 208 by a suitable technique such as a PVD process or a plating process. Lastly, the third electrode material layer is patterned by a photolithography and etching process to form the electrode 210.

In some embodiments, the electrodes 204, 206, and 210 respectively include various conductive materials, such as a metal, a metal alloy, a metal nitride, a metal silicide, a metal oxide, graphene, or a combination thereof. For example, the electrodes 204, 206, and 210 may respectively include aluminum (Al), titanium (Ti), copper (Cu), tungsten (W), platinum (Pt), palladium (Pd), osmium (Os), ruthenium (Ru), tantalum (Ta), or an alloy thereof, titanium nitride (TiN), tantalum nitride (TaN), tungsten nitride (WN), molybdenum nitride (MoN), TaSiN, TiSiN, WSiN, tungsten silicide, titanium silicide, cobalt silicide, zirconium silicide, platinum silicide, molybdenum silicide, copper silicide, nickel silicide, indium tin oxide (ITO), iridium oxide (IrO₂), rhenium oxide (ReO₂), rhenium trioxide (ReO₃), or a combination thereof. In some embodiments, the storage layers 204 and 208 respectively include a high-k dielectric material having a dielectric constant greater than 4, greater than 7, or even greater than 10. The high-k dielectric material may include hafnium oxide(HfO₂), hafnium silicate(HfSiO₄), hafnium silicon oxynitride (HfSiON), aluminum oxide (Al₂O₃), yttrium oxide (Y₂O₃), lanthanum oxide(La₂O₃), lanthanum aluminum oxide(LaAlO), tantalum oxide (Ta₂O₅), titanium oxide (TiO₂), zirconium oxide (ZrO₂), zirconium silicon oxide (ZrSiO₄), hafnium zirconium oxide (HfZrO), strontium bismuth tantalite (SrBi₂Ta₂O₉, SBT), or a combination thereof. In some embodiments, the storage layers 204 and 208 of the capacitor structure 200 and the dielectric layer 132 of the interconnect structure 130 are made of different materials.

As illustrated in FIG. 1A, the storage layer 204 is in physical contact with both the electrode 202 and the electrode 206 to form a metal-insulator-metal (MIM) structure. Meanwhile, the storage layer 208 is in physical contact with both the electrode 206 and the electrode 210 to form another MIM structure. That is, the capacitor structure 200 may be referred to as a MIM capacitor. In some embodiments, the storage layers 204 and 208 are utilized to store capacitance. As illustrated in FIG. 1A, the electrode 202, the storage layer 204, the electrode 206, the storage layer 208, and the electrode 210 are in physical contact with sidewalls of the topmost conductive vias 136. In other words, the capacitor structure 200 is electrically connected to the underlying conductive patterns 134 and/or the overlaying conductive pads 150 through the conductive vias 136. It should be noted that the number of the capacitor structure 200 illustrated in FIG. 1A is merely for illustrative purposes, and the disclosure is not limited thereto. In some alternative embodiments, more capacitor structures 200 may be embedded in the interconnect structure 130. In yet some alternative embodiments, the capacitor structure 200 is optional and may be omitted.

Referring to FIG. 1B, a plurality of bonding vias 170 is formed to penetrate through the passivation layer 160 and at least part of the dielectric layer 132 of the interconnect structure 130 to establish electrical connection with the conductive patterns 134 of the interconnect structure 130. In some embodiments, the bonding vias 170 may be considered as part of the die 100. As illustrated in FIG. 1B, the die 100 has an active surface AS1 and a rear surface RS1 opposite to the active surface AS1.

In some embodiments, the die 100 is capable of performing storage functions. For example, the die 100 may be Dynamic Random Access Memory (DRAM), Resistive Random Access Memory (RRAM), Static Random Access Memory (SRAM), or the like. However, the disclosure is not limited thereto. In some alternative embodiments, the die 100 may be a Central Process Unit (CPU) die, a Graphic Process Unit (GPU) die, Field-Programmable Gate Array (FPGA), or the like.

As illustrated in FIG. 1B, a bonding layer 300 is formed on the die 100. For example, the bonding layer 300 is formed on the active surface AS1 of the die 100. In some embodiments, the bonding layer 300 includes a dielectric layer 302 and a plurality of bonding pads 304. In some embodiments, the bonding pads 304 are embedded in the dielectric layer 302. In some embodiments, the bonding pads 304 of the bonding layer 300 are electrically connected to the bonding vias 170 of the die 100. That is, the bonding vias 170 electrically connect the interconnect structure 130 with the bonding pads 304. In some embodiments, the bonding pads 304 are also electrically connected to some of the conductive pads 150 through conductive vias therebetween. That is, in some embodiments, some of the conductive pads 150 are electrically floating while some of the conductive pads 150 are able to transmit signal to the bonding pads 304.

In some embodiments, the bonding vias 170 and the bonding pads 304 are formed via a dual damascene process. For example, the dielectric layer 302 is first formed on the passivation layer 160. In some embodiments, a material of the dielectric layer 302 includes oxides, such as silicon oxide or the like. Alternatively, the dielectric layer 302 may include polyimide, epoxy resin, acrylic resin, phenol resin, BCB, PBO, or any other suitable polymer-based dielectric material. The dielectric layer 302, for example, may be formed by suitable fabrication techniques, such as spin-on coating, CVD, PECVD, or the like. Subsequently, trenches and via holes (not shown) are formed in the dielectric layer 302 and the passivation layer 160 by removing portions of theses layers. In some embodiments, a width of the trench is greater than a width of the via hole. Thereafter, a conductive material (not shown) is filled into the via holes to form the bonding vias 170. Meanwhile, the conductive material (not shown) also fills into the trenches to from the bonding pads 304. That is, the bonding vias 170 and the bonding pads 304 are formed by simultaneously filling the via holes and the overlying trenches (not shown). However, the disclosure is not limited thereto. In some alternative embodiments, the bonding vias 170 may be formed before the dielectric layer 302 and the bonding pads 304. In some embodiments, a width of each bonding pad 304 is greater than a width of each underlying bonding via 170. In some embodiments, the bonding vias 170 and the bonding pads 304 include the same material. For example, the bonding vias 170 and the bonding pads 304 may be made of aluminum, titanium, copper, nickel, tungsten, or alloys thereof. In some embodiments, a top surface of the dielectric layer 302 and top surfaces of the bonding pads 304 are substantially located at the same level height to provide an appropriate top surface 300a for hybrid bonding.

Referring to FIG. 1C, a die 400 is provided. In some embodiments, the die 400 includes a semiconductor substrate 410, a plurality of devices 420, an interconnect structure 430, a plurality of conductive pads 440, a passivation layer 450, and a plurality of bonding vias 460. In some embodiments, the devices 420 are formed in the semiconductor substrate 410. The semiconductor substrate 410 and the devices 420 in the die 400 are respectively similar to the semiconductor substrate 110 and the devices 120 in the die 100, so the detailed descriptions thereof are omitted herein.

As illustrated in FIG. 1C, the interconnect structure 430 is disposed on the semiconductor substrate 410. In some embodiments, the interconnect structure 430 is electrically connected to the devices 420 formed in the semiconductor substrate 410. In some embodiments, the interconnect structure 430 includes a dielectric layer 432, a plurality of conductive patterns 434, and a plurality of conductive vias 436. The dielectric layer 432, the conductive patterns 434, and the conductive vias 436 of the interconnect structure 430 are respectively similar to the dielectric layer 132, the conductive patterns 134, and the conductive vias 136 of the interconnect structure 130, so the detailed descriptions thereof are omitted herein.

In some embodiments, the conductive pads 440, the passivation layer 450, and the bonding vias 460 are formed over the interconnect structure 430. In some embodiments, the conductive pads 440, the passivation layer 450, and the bonding vias 460 of the die 400 are respectively similar to the conductive pads 150, the passivation layer 160, and the bonding vias 170 of the die 100, so the detailed descriptions thereof are omitted herein. In some embodiments, the conductive pads 440 are electrically connected to the interconnect structure 430. In some embodiments, the bonding vias 460 are formed to penetrate through the passivation layer 450 and at least part of the dielectric layer 432 of the interconnect structure 430 to establish electrical connection with the conductive patterns 434 of the interconnect structure 430. That is, a portion of each bonding via 460 is embedded in the passivation layer 450 while another portion of the same bonding via 460 is embedded in the dielectric layer 432 of the interconnect structure 430.

As illustrated in FIG. 1C, the die 400 has an active surface AS2 and a rear surface RS2 opposite to the active surface AS2. In some embodiments, the die 400 is capable of performing storage functions. For example, the die 400 may be DRAM, RRAM, SRAM, or the like. However, the disclosure is not limited thereto. In some alternative embodiments, the die 400 may be a CPU die, a GPU die, FPGA, or the like.

As illustrated in FIG. 1C, a capacitor structure 500 is formed to be embedded in the interconnect structure 430. For example, the capacitor structure 500 is embedded in the dielectric layer 432 of the interconnect structure 430. In some embodiments, the capacitor structure 500 includes an electrode 502, a storage layer 504, an electrode 506, a storage layer 508, and an electrode 510. In some embodiments, the electrode 502, the storage layer 504, the electrode 506, the storage layer 508, and the electrode 510 are respectively similar to the electrode 202, the storage layer 204, the electrode 206, the storage layer 208, and the electrode 210 of the capacitor structure 200, so the detailed descriptions thereof are omitted herein. In some embodiments, the storage layers 504 and 508 of the capacitor structure 500 and the dielectric layer 432 of the interconnect structure 430 are made of different materials.

As illustrated in FIG. 1C, the storage layer 504 is in physical contact with both the electrode 502 and the electrode 506 to form a MIM structure. Meanwhile, the storage layer 508 is in physical contact with both the electrode 506 and the electrode 510 to form another MIM structure. That is, the capacitor structure 500 may be referred to as a MIM capacitor. In some embodiments, the storage layers 504 and 508 are utilized to store capacitance. As illustrated in FIG. 1C, the electrode 502, the storage layer 504, the electrode 506, the storage layer 508, and the electrode 510 are in physical contact with sidewalls of the bottommost conductive vias 436. In other words, the capacitor structure 500 is electrically connected to the overlaying conductive patterns 434 and/or the underlying conductive pads 440 through the conductive vias 436. It should be noted that the number of the capacitor structure 500 illustrated in FIG. 1C is merely for illustrative purposes, and the disclosure is not limited thereto. In some alternative embodiments, more capacitor structures 500 may be embedded in the interconnect structure 430. In yet some alternative embodiments, the capacitor structure 500 is optional and may be omitted.

As illustrated in FIG. 1C, a bonding layer 600 is formed on the die 400. For example, the bonding layer 600 is formed on the active surface AS2 of the die 400. In some embodiments, the bonding layer 600 includes a dielectric layer 602 and a plurality of bonding pads 604. The dielectric layer 602 and the bonding pads 604 of the bonding layer 600 are respectively similar to the dielectric layer 302 and the bonding pads 304 of the bonding layer 300, so the detailed descriptions thereof are omitted herein. In some embodiments, the bonding pads 604 are electrically connected to the bonding vias 460. That is, the bonding via 460 electrically connects the interconnect structure 430 with the bonding pads 604. In some embodiments, the bonding pads 604 are also electrically connected to the conductive pads 440. In some embodiments, a bottom surface of the dielectric layer 602 and bottom surfaces of the bonding pads 604 are substantially located at the same level height to provide an appropriate bottom surface 600a for hybrid bonding.

In some embodiments, the die 400 is placed over the bonding layer 300 such that the die 400 is bonded to the die 100. In some embodiments, the die 400 is bonded to the die 100 through a hybrid bonding process. For example, the die 400 is bonded to the die 100 through the bonding layers 300 and 600. As illustrated in FIG. 1C, the boding layer 600 is located between the die 100 and the die 400. Meanwhile, the bonding layer 300 is located between the bonding layer 600 and the die 100. The hybrid bonding process will be described in detail below.

First, the die 400 having the boding layer 600 formed thereon may be picked-and-placed onto the bonding layer 300 such that the die 400 is electrically connected to the die 100. In some embodiments, the die 400 is placed such that the bottom surface 600a of the bonding layer 600 is in contact with the top surface 300a of the bonding layer 300. Meanwhile, the bonding pads 604 of the bonding layer 600 are substantially aligned and in direct contact with the corresponding bonding pads 304 of the bonding layer 300. In some embodiments, to facilitate the hybrid bonding between the die 100 and the die 400, surface preparation for bonding surfaces (i.e. the top surfaces 300a and the bottom surface 600a) of the bonding layers 300 and 600 may be performed. The surface preparation may include surface cleaning and activation, for example. Surface cleaning may be performed on the top surfaces 300a and the bottom surface 600a to remove particles on the bonding surface of the dielectric layer 302, the bonding surfaces of the bonding pads 304, the bonding surface of the dielectric layer 602, and the bonding surfaces of the bonding pads 604. In some embodiments, the top surfaces 300a and the bottom surface 600a may be cleaned by wet cleaning, for example. Not only particles are removed, but also native oxide formed on the bonding surfaces of the bonding pads 304 and the bonding pads 604 may be removed. The native oxide formed on the bonding surfaces of the bonding pads 304 and the bonding pads 604 may be removed by chemicals used in wet cleaning processes, for example.

After cleaning the top surfaces 300a and the bottom surface 600a, activation of the bonding surfaces of the dielectric layer 302 and the dielectric layer 602 may be performed for development of high bonding strength. In some embodiments, plasma activation may be performed to treat the bonding surfaces of the dielectric layer 302 and the dielectric layer 602. When the activated bonding surface of the dielectric layer 602 is in contact with the activated bonding surface of the dielectric layer 302, the dielectric layer 302 of the bonding layer 300 and the dielectric layer 602 of the bonding layer 600 are pre-bonded. In other words, the die 400 is pre-bonded to the die 100.

After pre-bonding the die 400 onto the die 100, hybrid bonding of the die 400 and the die 100 is performed. The hybrid bonding of the die 400 and the die 100 may include a thermal treatment for dielectric bonding and a thermal annealing for conductor bonding. In some embodiments, the thermal treatment for dielectric bonding is performed to strengthen the bonding between the dielectric layer 602 and the dielectric layer 302. For example, the thermal treatment for dielectric bonding may be performed at temperature ranging from about 200° C. to about 400° C. After performing the thermal treatment for dielectric bonding, the thermal annealing for conductor bonding is performed to facilitate the bonding between the bonding pads 604 and the bonding pads 304. For example, the thermal annealing for conductor bonding may be performed at temperature ranging from about 150° C. to about 400° C. After performing the thermal annealing for conductor bonding, the dielectric layer 602 is hybrid bonded to the dielectric layer 302 and the bonding pads 604 are hybrid bonded to the bonding pads 304. For example, the dielectric layer 602 is directly in contact with the dielectric layer 302. Similarly, the bonding pads 604 are directly in contact with the bonding pads 304. As such, the bonding layer 600 is hybrid bonded to the bonding layer 300. In other words, the die 400 is hybrid bonded to the die 100. Although FIG. 1C illustrated that the bonding pads 304 and the bonding pads 604 have sharp corners (the sidewalls are perpendicular to the top/bottom surfaces), the disclosure is not limited thereto. In some alternative embodiments, after the bonding pads 604 are hybrid bonded to the bonding pads 304, corner rounding of the bonding pads may occur. For example, the corners of the bonding pads 304 facing the bonding pads 604 are rounded. Similarly, the corners of the bonding pads 604 facing the bonding pads 304 are also rounded. That is, edges of the top surface of each bonding pad 304 are rounded. Similarly, edges of the bottom surface of each bonding pad 604 are also rounded. Moreover, although FIG. 1C illustrated that the bonding pads 304 and the bonding pads 604 have the same width and sidewalls of the bonding pads 304 are aligned with sidewalls of the corresponding bonding pads 604, the disclosure is not limited thereto. In some alternative embodiments, the width of each bonding pad 304 may be smaller than or larger than the width of each bonding pad 604.

In some embodiments, the die 100 and the die 400 are both in wafer form, so the foregoing hybrid bonding process may be referred to as a “wafer-to-wafer bonding process.” However, the disclosure is not limited thereto. In some alternative embodiments, the die is in wafer form while the die 400 is in chip form, and the foregoing hybrid bonding process may be referred to as a “chip-on-wafer bonding process.” In some embodiments, since the active surface AS1 of the die 100 faces the active surface AS2 of the die 400, the bonding of the die 400 with the die 100 may be considered as face-to-face bonding.

Referring to FIG. 1C and FIG. 1D, the structure illustrated in FIG. 1C is flipped upside down and is attached to a carrier C2 through a bonding film BF. In some embodiments, the carrier C2 is made of silicon, polymer, polymer composite, metal foil, ceramic, glass, glass epoxy, tape, or other suitable material for structural support. In some embodiments, the structure illustrated in FIG. 1C may be bonded to the carrier C2 and the bonding film BF through fusion bonding.

Referring to FIG. 1D and FIG. 1E, the carrier C1 is removed. In some embodiments, the carrier C1 is removed through an etching process, a grinding process, a de-bonding process, or the like. For example, the carrier C1 may be removed through a chemical mechanical polishing (CMP) process. After the carrier C1 is removed, the die 100 is exposed. For example, the rear surface RS1 of the die 100 is exposed.

Referring to FIG. 1E and FIG. 1F, a portion of the die 100 is removed. For example, the die 100 is thinned until the TSVs 140 are exposed. That is, the die 100 is thinned from the rear surface RS1. In some embodiments, the die 100 is thinned or planarized through a grinding process, such as a mechanical grinding process, a CMP process, or the like. In some embodiments, after the TSVs 140 are exposed, the die 100 may be further thinned to reduce the overall thickness of the die 100. As illustrated in FIG. 1F, after the thinning process, the TSVs 140 penetrate through the semiconductor substrate 110 of the die 100.

Referring to FIG. 1F and FIG. 1G, a portion of the die 100 is removed. For example, a portion of the semiconductor substrate 110 of the die 100 is removed. As illustrated in FIG. 1G, at least a portion of each TSV 140 protrudes out from the semiconductor substrate 110 of the die 100. That is, a top surface of each TSV 140 is located at a level height higher than that of the rear surface RS1 of the die 100. In some embodiments, the semiconductor substrate 110 is partially removed through an etching process. The etching process includes, for example, an isotropic etching process and/or an anisotropic etching process. For example, the semiconductor substrate 110 may be partially removed through a wet etching process, a drying etching process, or a combination thereof.

Referring to FIG. 1H, a protection layer PL is formed on the rear surface RS1 of the die 100. In some embodiments, the protection layer PL includes a molding compound, a molding underfill, or the like. Alternatively, the protection layer PL may be made of a polymeric material, such as polyimide, epoxy resin, acrylic resin, phenol resin, BCB, PBO, or other suitable polymer-based dielectric materials. In some embodiments, the protection layer PL includes fillers. Alternatively, the protection layer PL may be free of fillers. As illustrated in FIG. 1H, the protruding portion of each TSV 140 is laterally encapsulated by the protection layer PL. In some embodiments, the protection layer PL is formed by the following steps. First, a protection material layer (not shown) is formed on the semiconductor substrate 110 of the die 100. Subsequently, a grinding or thinning process is performed on the protection material layer until the TSVs 140 are revealed. The thinning process includes, for example, a mechanical grinding process, a CMP process, or the like.

Referring to FIG. 1I, a redistribution structure 700, a capacitor structure 800, a plurality of conductive pads 900, a passivation layer 1000, and a plurality of under-bump metallurgy (UBM) patterns 1100 are formed on the die 100 and the protection layer PL.

As illustrated in FIG. 1I, the redistribution structure 700 and the die 400 are located on two opposite sides of the die 100. Meanwhile, the protection layer PL is sandwiched between the die 100 and the redistribution structure 700. In some embodiments, the redistribution structure 700 includes a plurality of conductive patterns 702, a plurality of dielectric layers 704, and a plurality of conductive vias 706. In some embodiments, the conductive patterns 702 are embedded in the dielectric layers 704. In some embodiments, the conductive patterns 702 located at different level heights are connected to each other through the conductive vias 706. In other words, the conductive patterns 702 are electrically connected to each other through the conductive vias 706. In some embodiments, some of the bottommost conductive patterns 702 are directly in contact with the TSVs 140 of the die 100. In other words, the TSVs 140 electrically connect the interconnect structure 130 and the redistribution structure 700.

In some embodiments, a material of the conductive patterns 702 and the conductive vias 706 includes aluminum, titanium, copper, nickel, tungsten, or alloys thereof. The conductive patterns 702 and the conductive vias 706 may be formed by, for example, electroplating, deposition, and/or photolithography and etching. In some embodiments, the conductive patterns 702 and the underlying conductive vias 706 may be formed simultaneously. In some embodiments, the material of the dielectric layers 704 includes polyimide, epoxy resin, acrylic resin, phenol resin, BCB, PBO, or any other suitable polymer-based dielectric material. The dielectric layers 704, for example, may be formed by suitable fabrication techniques such as spin-on coating, CVD, PECVD, or the like. It should be noted that the number of the conductive patterns 702, the number of the dielectric layers 704, and the number of the conductive vias 706 illustrated in FIG. 1I are merely for illustrative purposes, and the disclosure is not limited thereto. In some alternative embodiments, fewer or more layers of the conductive patterns 702, the dielectric layers 704, or the conductive vias 706 may be formed depending on the circuit design.

In some embodiments, during the formation of the redistribution structure 700, the capacitor structure 800 is simultaneously formed. For example, the capacitor structure 800 is embedded in the dielectric layer 704 of the redistribution structure 700. It should be noted that although FIG. 1I illustrated that the capacitor structure 800 is embedded in the topmost dielectric layer 704, the disclosure is not limited thereto. In some alternative embodiments, the capacitor structure 800 may be embedded in other dielectric layers 704 of the redistribution structure. It should be noted that the number of the capacitor structure 800 illustrated in FIG. 1I is merely for illustrative purposes, and the disclosure is not limited thereto. In some alternative embodiments, more capacitor structures 800 may be embedded in the dielectric layer 704 of the redistribution structure 700.

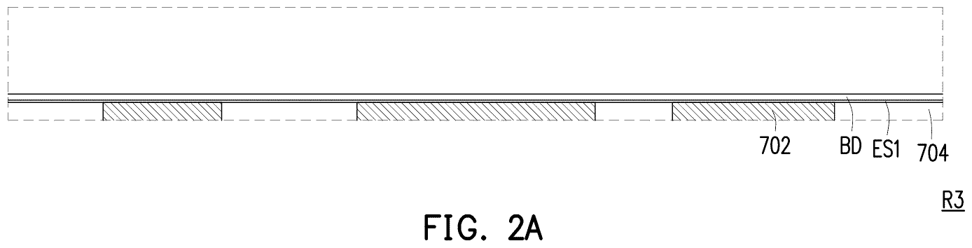

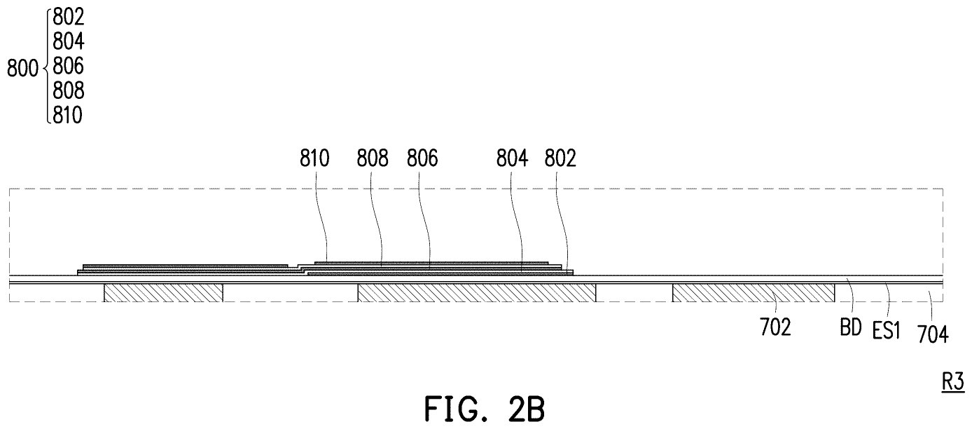

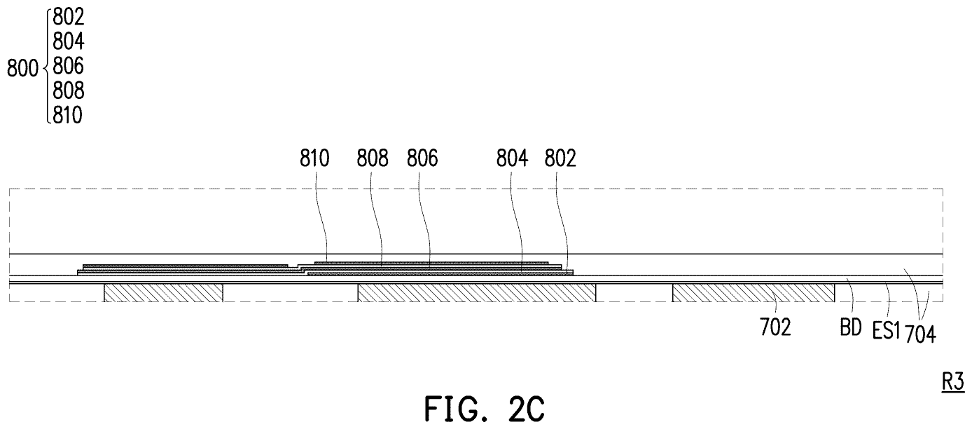

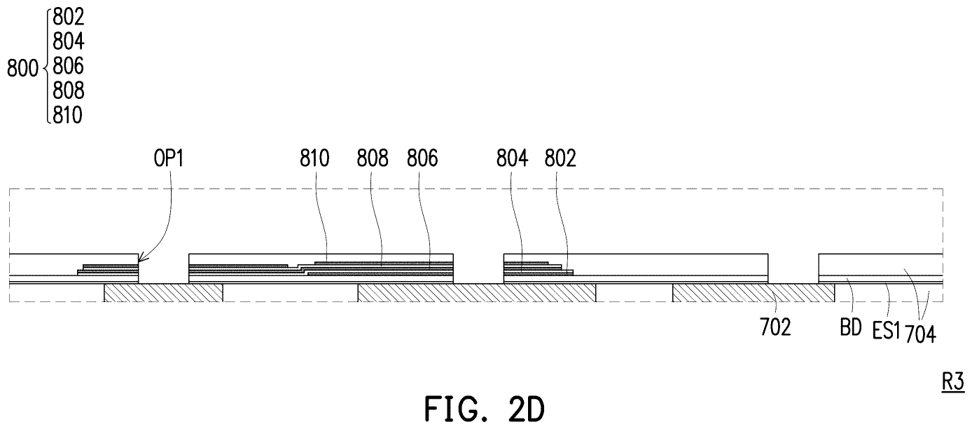

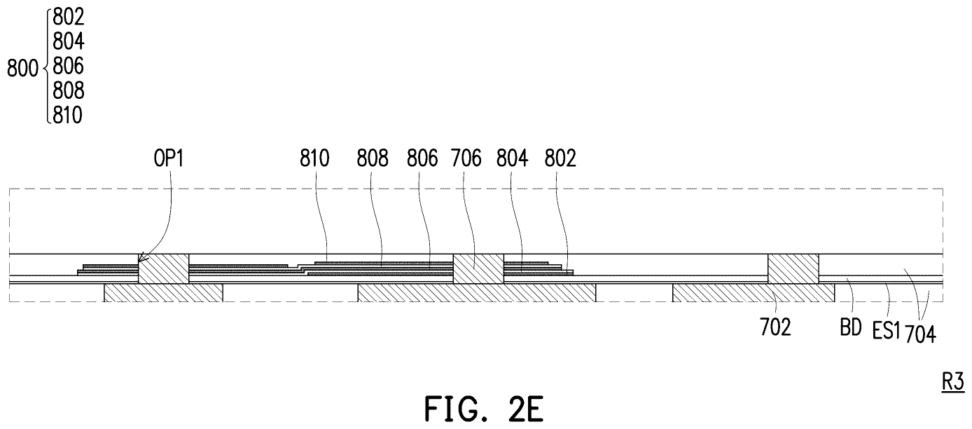

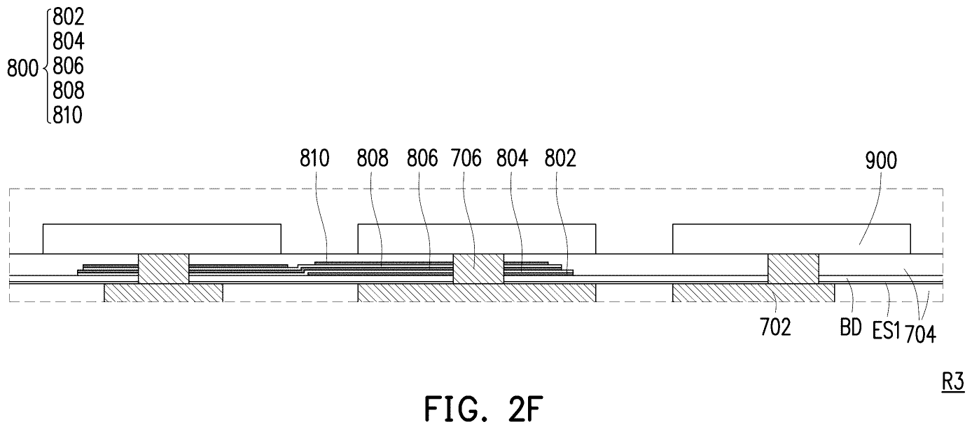

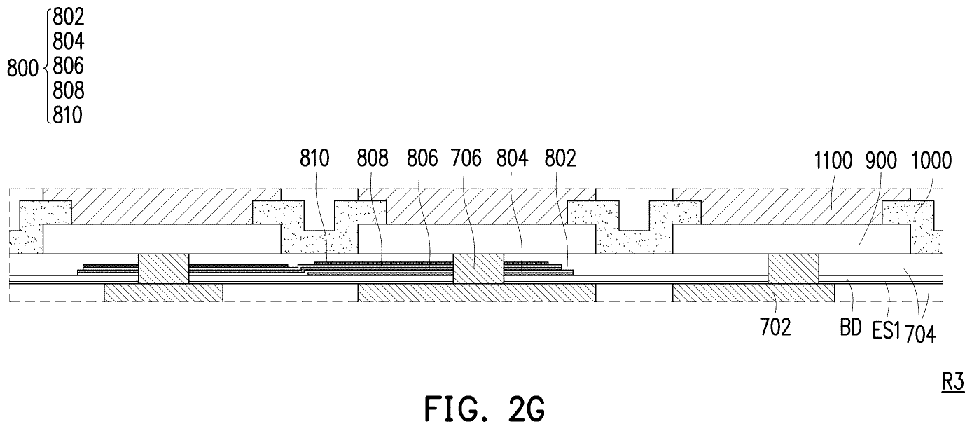

In addition, after the redistribution structure 700 and the capacitor structure 800 are formed, the conductive pads 900, the passivation layer 1000, and the UBM patterns 1100 are sequentially formed on redistribution structure 700. The formation methods and the structures of the capacitor structure 800, the conductive pads 900, the passivation layer 1000, and the UBM patterns 1100 will be described below in conjunction with FIG. 2A to FIG. 2G.

FIG. 2A to FIG. 2G are enlarged views of a region R3 in FIG. 1J to illustrate a manufacturing process of the capacitor 800, the conductive pads 900, the passivation layer 1000, and the UBM patterns 1100. Referring to FIG. 2A, after the conductive patterns 702 (i.e., the topmost conductive patterns 702 in FIG. 1I) and the dielectric layer 704 adjacent thereto are formed, an etch stop layer ES1 is formed on top surfaces of these conductive patterns 702 and this dielectric layer 704. In some embodiments, a material of the etch stop layer ES1 includes silicon carbide, silicon nitride, or the like. In some embodiments, the etch stop layer ES1 is formed by any suitable method, such as CVD, spin-on coating, or the like. Thereafter, a buffer dielectric layer BD is formed on the etch stop layer ES1. In some embodiments, a material of the buffer dielectric layer BD includes oxides, such as silicon oxide or the like. The buffer dielectric layer BD, for example, may be formed by suitable fabrication techniques, such as spin-on coating, CVD, PECVD, or the like.

Referring to FIG. 2B, the capacitor structure 800 is formed on the buffer dielectric layer BD. In some embodiments, the capacitor structure 800 includes an electrode 802, a storage layer 804, an electrode 806, a storage layer 808, and an electrode 810. In some embodiments, the capacitor structure 800 is formed by the following steps. First, a first electrode material layer (not shown) is conformally formed on a top surface of the buffer dielectric layer BD by a suitable technique such as a PVD process or a plating process. Thereafter, the first electrode material layer is patterned by a photolithography and etching process to form the electrode 802. After the electrode 802 is formed on the buffer dielectric layer BD, a first storage material layer (not shown) is conformally formed on the electrode 802 and the buffer dielectric layer BD by a suitable technique such as CVD, PECVD, FCVD, HDP-CVD, SACVD, PVD, or ALD. Thereafter, the first storage material layer is patterned by a photolithography and etching process to form the storage layer 804. The storage layer 804 covers the electrode 802 and the buffer dielectric layer BD. Then, a second electrode material layer (not shown) is conformally formed on a top surface of the storage layer 804 by a suitable technique such as a PVD process or a plating process. Thereafter, the second electrode material layer is patterned by a photolithography and etching process to form the electrode 806. After the electrode 806 is formed on the storage layer 804, a second storage material layer (not shown) is conformally formed on the electrode 806 by a suitable technique such as CVD, PECVD, FCVD, HDP-CVD, SACVD, PVD, or ALD. Thereafter, the second storage material layer is patterned by a photolithography and etching process to form the storage layer 808. Subsequently, a third electrode material layer (not shown) is conformally formed on a top surface of the storage layer 808 by a suitable technique such as a PVD process or a plating process. Lastly, the third electrode material layer is patterned by a photolithography and etching process to form the electrode 810.

In some embodiments, the electrodes 802, 806, and 810 respectively include various conductive materials, such as a metal, a metal alloy, a metal nitride, a metal silicide, a metal oxide, graphene, or a combination thereof. For example, the electrodes 802, 806, and 810 may respectively include Al, Ti, Cu, W, Pt, Pd, Os, Ru, Ta, or an alloy thereof, TiN, TaN, WN, MoN, TaSiN, TiSiN, WSiN, tungsten silicide, titanium silicide, cobalt silicide, zirconium silicide, platinum silicide, molybdenum silicide, copper silicide, nickel silicide, ITO, IrO₂, ReO₂, ReO₃, or a combination thereof. In some embodiments, the storage layers 804 and 808 respectively include a high-k dielectric material having a dielectric constant greater than 4, greater than 7, or even greater than 10. The high-k dielectric material may include HfO₂, HfSiO₄, HfSiON, Al₂O₃, Y₂O₃, La₂O₃, LaAlO, Ta₂O₅, TiO₂, ZrO₂, ZrSiO₄, HfZrO, SrBi₂Ta₂O₉ (SBT), or a combination thereof.

As illustrated in FIG. 2B, the electrode 806 is disposed over the electrode 802, and the storage layer 804 is between the electrode 802 and the electrode 806. For example, the storage layer 804 is in physical contact with both the electrode 802 and the electrode 806 to form a MIM structure. Meanwhile, the electrode 810 is disposed over the electrode 806, and the storage layer 808 is between the electrode 806 and the electrode 810. For example, the storage layer 808 is in physical contact with both the electrode 806 and the electrode 810 to form another MIM structure. That is, the capacitor structure 800 may be referred to as a MIM capacitor. In some embodiments, the storage layers 804 and 808 are utilized to store capacitance. As illustrated in FIG. 2C, the capacitor structure 800 partially exposes the underlying buffer dielectric layer BD. In some embodiments, a sidewall of the electrode 802 is aligned with a sidewall of the storage layer 804. For example, the right sidewall of the electrode 802 is aligned with the right sidewall of the storage layer 804. In some embodiments, a sidewall of the electrode 806 is aligned with a sidewall of the storage layer 808, and another sidewall of the electrode 806 is aligned with a sidewall of the storage layer 804. For example, the right sidewall of the electrode 806 is aligned with the right sidewall of the storage layer 808, and the left sidewall of the electrode 806 is aligned with the left sidewall of the storage layer 804. As illustrated in FIG. 2B, the electrode 806 partially exposes the underlying storage layer 804. In some embodiments, a sidewall of the electrode 810 is aligned with a sidewall of the storage layer 808. For example, the left sidewall of the electrode 810 is aligned with the left sidewall of the storage layer 808. As illustrated in FIG. 2B, the electrode 810 partially exposes the underlying storage layer 808.

Referring to FIG. 2C, after the capacitor structure 800 is formed, the dielectric layer 704 (i.e., the topmost dielectric layer 704 in FIG. 1I) is formed on the buffer dielectric layer BD and the capacitor structure 800. For example, the dielectric layer 704 is in physical contact with both the buffer dielectric layer BD and the capacitor structure 800. In some embodiments, the storage layers 804 and 808 of the capacitor structure 800 and the dielectric layers 704 of the redistribution structure 700 are made of different materials.

Referring to FIG. 2D, a portion of the etch stop layer ES1, a portion of the buffer dielectric layer BD, a portion of the capacitor structure 800, and a portion of the topmost dielectric layer 704 are removed to form a plurality of openings OP1. For example, the etch stop layer ES1, the buffer dielectric layer BD, the electrode 802, the storage layer 804, the electrode 806, the storage layer 808, the electrode 810, and the topmost dielectric layer 704 are patterned by a patterning process to form the openings OP1. The patterning process includes photolithography and one or more etching processes, for example. In some embodiments, the openings OP1 penetrate through the topmost dielectric layer 704, the capacitor structure 800, the buffer dielectric layer BD, and the etch stop layer ES1 to expose the underlying conductive patterns 702.

Referring to FIG. 2E, the conductive vias 706 (i.e., the topmost conductive vias 706 in FIG. 1I) are formed in the openings OP1. In some embodiments, the conductive vias 706 fill up the openings OP1. As illustrated in FIG. 2E, top surfaces of the conductive vias 706 are coplanar with a top surface of the topmost dielectric layer 704. At this stage, the formation of the redistribution structure 700 is essentially completed. As illustrated in FIG. 2A to FIG. 2E, the capacitor structure 800 is formed during the formation of the redistribution structure 700.

Referring to FIG. 1I and FIG. 2F, after the redistribution structure 700 is formed, the conductive pads 900 are formed over the redistribution structure 700. In some embodiments, a material of the conductive pads 900 includes aluminum, titanium, copper, nickel, tungsten, or alloys thereof. In some embodiments, the material of the conductive pads 900 is different from the material of the conductive patterns 702 of the redistribution structure 700. For example, the conductive patterns 702 of the redistribution structure 700 may be made of copper while the conductive pads 900 may be made of aluminum. However, the disclosure is not limited thereto. In some alternative embodiments, the material of the conductive pads 900 may be the same as the material of the conductive patterns 702 of the redistribution structure 700. In some embodiments, the conductive pads 900 may be formed by, for example, electroplating, deposition, and/or photolithography and etching. As illustrated in FIG. 2F, the conductive pads 900 are directly in contact with the conductive vias 706, thereby rendering electrical connection with the redistribution structure 700. In some embodiments, the conductive pads 900 are used to establish electrical connection with other components (not shown) subsequently formed or provided. In some alternative embodiments, the conductive pads 900 may be test pads.

As illustrated in FIG. 2F, the electrode 802, the storage layer 804, the electrode 806, the storage layer 808, and the electrode 810 are in physical contact with sidewalls of the conductive vias 706. In other words, the capacitor structure 800 is electrically connected to the underlying conductive patterns 702 and/or the overlaying conductive pads 900 through the conductive vias 706.

Referring to FIG. 1I and FIG. 2G, after the conductive pads 900 are formed, the passivation layer 1000 is formed on the redistribution structure 700 and the conductive pads 900 to partially cover the conductive pads 900. In some embodiments, a material of the passivation layer 1000 includes oxides, such as silicon oxide or the like. Alternatively, the passivation layer 1000 may include polyimide, epoxy resin, acrylic resin, phenol resin, BCB, PBO, or any other suitable polymer-based dielectric material. The passivation layer 1000, for example, may be formed by suitable fabrication techniques, such as spin-on coating, CVD, PECVD, or the like. In some embodiments, the passivation layer 1000 is formed to expose at least a portion of each conductive pad 900.

Thereafter, the UBM patterns 1100 are formed over the conductive pads 900 and the passivation layer 1000. In some embodiments, the UBM patterns 1100 are in direct contact with the portion of the conductive pads 900 exposed by the passivation layer 1000. That is, the UBM patterns 1100 are electrically connected to the conductive pads 900 and the redistribution structure 700. In some embodiments, a material of the UBM patterns 1100 includes aluminum, titanium, copper, nickel, tungsten, or alloys thereof. The UBM patterns 1100 may be formed by, for example, electroplating, deposition, and/or photolithography and etching.

Referring to FIG. 1J, a plurality of conductive terminals 1200 is formed on the UBM patterns 1100. In some embodiments, the conductive terminals 1200 are attached to the UBM patterns 1100 through a solder flux. In some embodiments, the conductive terminals 1200 are, for example, solder balls, ball grid array (BGA) balls, or controlled collapse chip connection (C4) bumps. In some embodiments, the conductive terminals 1200 are made of a conductive material with low resistivity, such as Sn, Pb, Ag, Cu, Ni, Bi, or an alloy thereof. As illustrated in FIG. 1J, the capacitor structure 800 is between the die 100 and the conductive terminals 1200.

After the conductive terminals 1200 are formed, a singulation process is performed to form a plurality of integrated circuits 10. In some embodiments, the dicing process or the singulation process typically involves dicing with a rotating blade or a laser beam. In other words, the dicing or singulation process is, for example, a laser cutting process, a mechanical cutting process, or other suitable processes. In some embodiments, the die 100 is stacked on and bonded to the die 400. In other words, multiple dies 100 and 400 are integrated into a single integrated circuit 10. As such, the integrated circuit 10 may be referred to as a “system on integrated circuit (SOIC) chip.”

As illustrated in FIG. 1J, the capacitor structure 800 is integrated into the redistribution structure 700 of the integrated circuit 10. Since the location of the capacitor structure 800 is close to a power source, the phenomena of IR drop may be sufficiently reduced, thereby rendering higher operation performance and lower power consumption. In addition, with the integration of the capacitor structure 800 into the redistribution structure 700, the existence of the capacitor structure 200 and the capacitor structure 500 may be optional, thereby releasing/free up routing area in the interconnect structures 130 and 430 of the dies 100 and 400. As such, the circuit designs in the dies 100 and 400 may be more flexible, and the overall size of the dies 100 and 400 may be reduced. Moreover, since the integration of the capacitor structure 800 into the redistribution structure 700 is compatible with the existing process, the manufacturing complexity of the integrated circuit 10 may be sufficiently simplified.

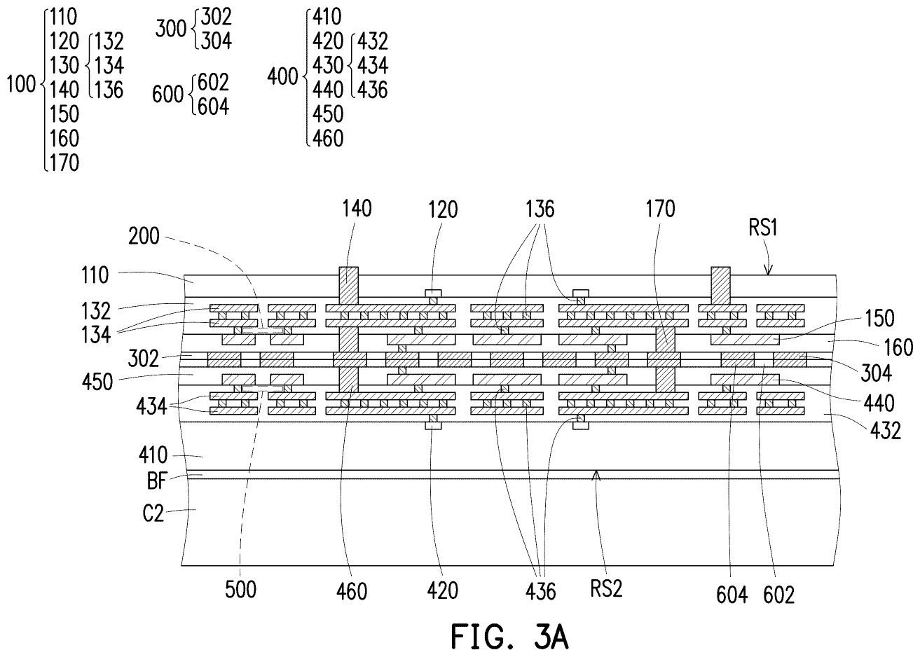

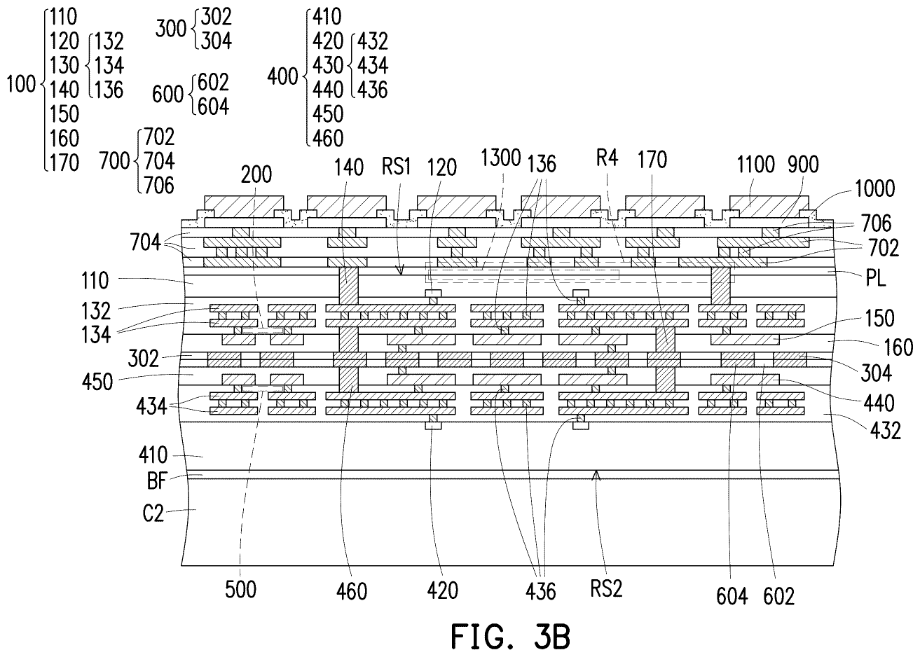

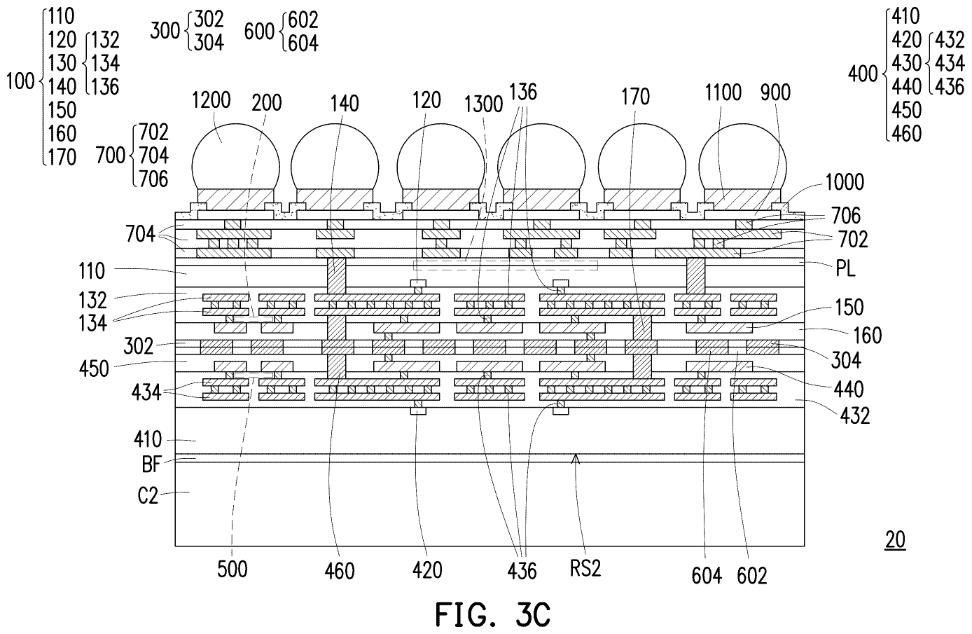

FIG. 3A to FIG. 3C are schematic cross-sectional views illustrating a manufacturing process of an integrated circuit 20 in accordance with some alternative embodiments of the disclosure. Referring to FIG. 3A, the structure illustrated in FIG. 3A may be formed by the process described in FIG. 1A to FIG. 1G. In other words, the structure illustrated in FIG. 3A is similar to the structure illustrated in FIG. 1G, so similar elements are denoted by the same reference numeral, and the detailed descriptions thereof are omitted herein.

Referring to FIG. 3B, a capacitor structure 1300, a protection layer PL, a redistribution structure 700, a plurality of conductive pads 900, a passivation layer 1000, and a plurality of UBM patterns 1100 are formed on the die 100. In some embodiments, the protection layer PL is formed on the rear surface RS1 of the die 100. As illustrated in FIG. 3B, the redistribution structure 700 and the die 400 are located on two opposite sides of the die 100. Meanwhile, the protection layer PL is sandwiched between the die 100 and the redistribution structure 700. For example, the protection layer PL is sandwiched between the semiconductor substrate 110 of die 100 and the redistribution structure 700. In some embodiments, the redistribution structure 700 includes a plurality of conductive patterns 702, a plurality of dielectric layers 704, and a plurality of conductive vias 706. In some embodiments, the conductive patterns 702 are embedded in the dielectric layers 704. In some embodiments, the conductive patterns 702 located at different level heights are connected to each other through the conductive vias 706. In other words, the conductive patterns 702 are electrically connected to each other through the conductive vias 706. In some embodiments, some of the bottommost conductive patterns 702 are directly in contact with the TSVs 140 of the die 100. In other words, the TSVs 140 electrically connect the interconnect structure 130 and the redistribution structure 700.

In some embodiments, a material of the conductive patterns 702 and the conductive vias 706 includes aluminum, titanium, copper, nickel, tungsten, or alloys thereof. The conductive patterns 702 and the conductive vias 706 may be formed by, for example, electroplating, deposition, and/or photolithography and etching. In some embodiments, the conductive patterns 702 and the underlying conductive vias 706 may be formed simultaneously. In some embodiments, the material of the dielectric layers 704 includes polyimide, epoxy resin, acrylic resin, phenol resin, BCB, PBO, or any other suitable polymer-based dielectric material. The dielectric layers 704, for example, may be formed by suitable fabrication techniques such as spin-on coating, CVD, PECVD, or the like. It should be noted that the number of the conductive patterns 702, the number of the dielectric layers 704, and the number of the conductive vias 706 illustrated in FIG. 3B are merely for illustrative purposes, and the disclosure is not limited thereto. In some alternative embodiments, fewer or more layers of the conductive patterns 702, the dielectric layers 704, or the conductive vias 706 may be formed depending on the circuit design.

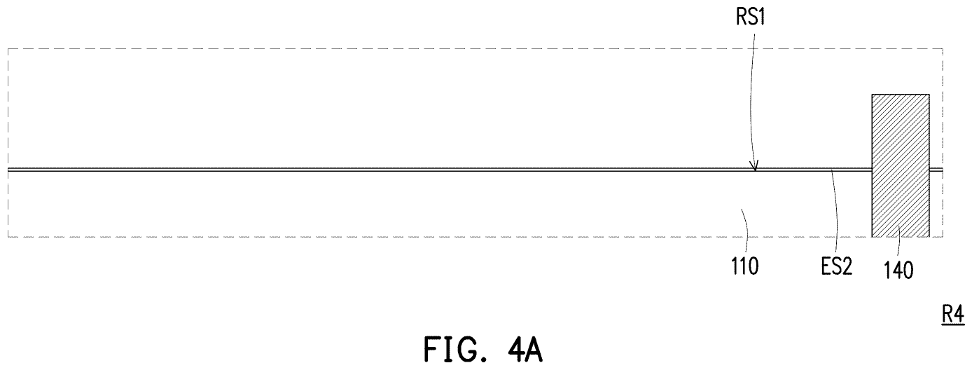

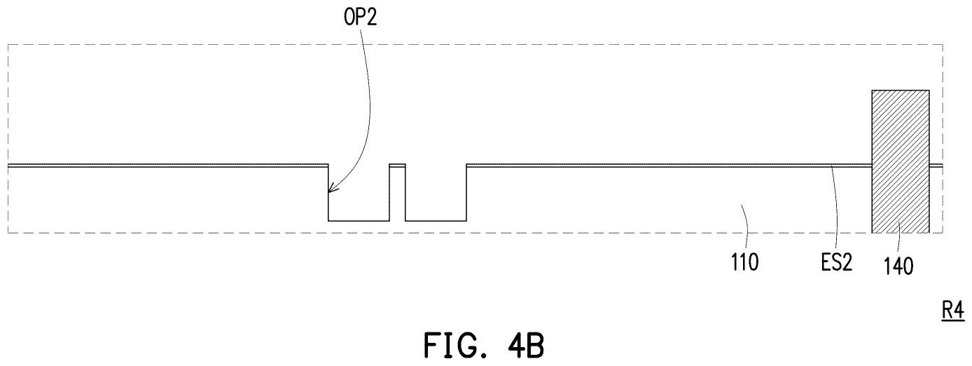

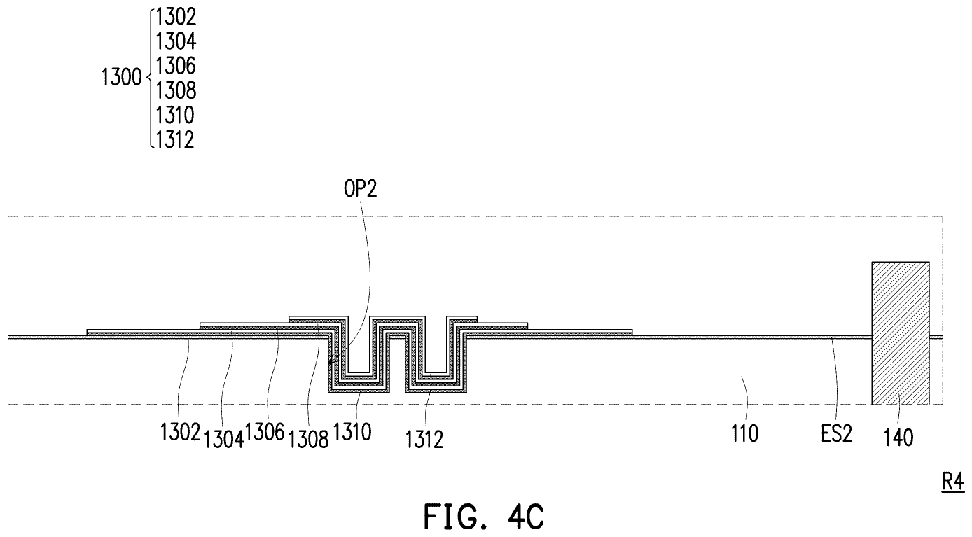

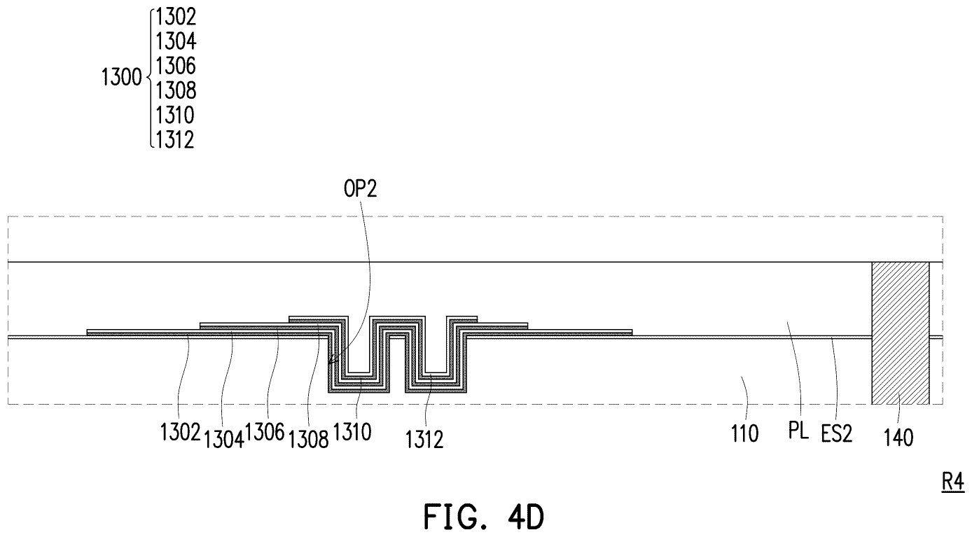

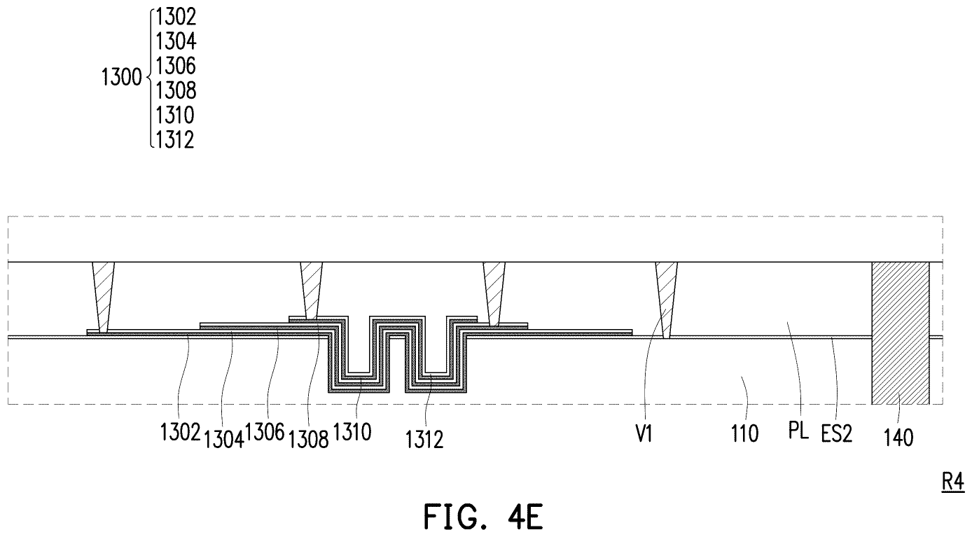

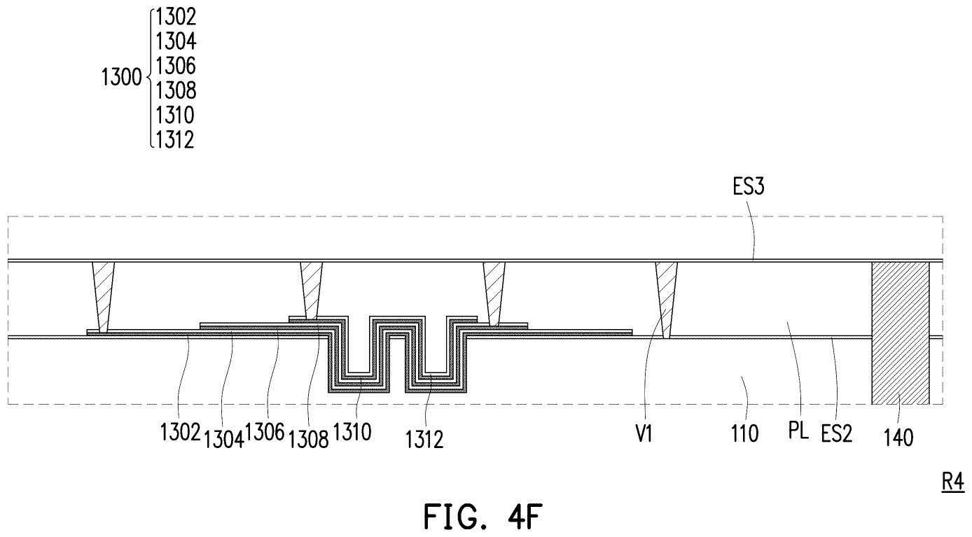

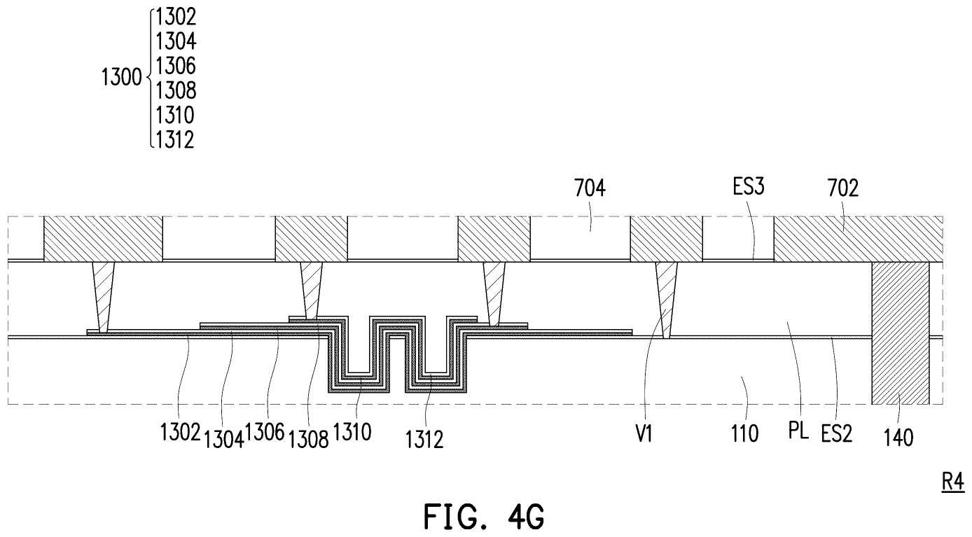

In some embodiments, the formation of the capacitor structure 1300 is prior to the formation of the protection layer PL and the formation of the redistribution structure 700. For example, the capacitor structure 1300 is partially embedded in the semiconductor substrate 110 of the die 100. Meanwhile, the capacitor structure 1300 is also partially embedded in the protection layer PL. It should be noted that the number of the capacitor structure 1300 illustrated in FIG. 3B is merely for illustrative purposes, and the disclosure is not limited thereto. In some alternative embodiments, more capacitor structures 1300 may be embedded in the semiconductor substrate 110 of the die and the protection layer PL. The formation methods and the structures of the capacitor structure 1300, the protection layer PL, the conductive patterns 702, and the dielectric layers 704 will be described below in conjunction with FIG. 4A to FIG. 4G.

FIG. 4A to FIG. 4G are enlarged views of a region R4 in FIG. 3B to illustrate a manufacturing process of the capacitor structure 1300, the protection layer PL, the conductive patterns 702, and the dielectric layers 704.

Referring to FIG. 4A, an etch stop layer ES2 is formed on the rear surface RS1 of the die 100. For example, the etch stop layer ES2 is in physical contact with the semiconductor substrate 110 of the die 100. In some embodiments, a material of the etch stop layer ES2 includes silicon carbide, silicon nitride, or the like. In some embodiments, the etch stop layer ES2 is formed by any suitable method, such as CVD, spin-on coating, or the like. In some embodiments, the etch stop layer ES2 laterally surrounds the TSV 140. As illustrated in FIG. 4A, the TSV 140 protrudes out from a top surface of the etch stop layer ES2.

Referring to FIG. 4B, a portion of the etch stop layer ES2 and a portion of the semiconductor substrate 110 are removed to form a plurality of openings OP2. For example, the etch stop layer ES2 and the semiconductor substrate 110 are patterned by a patterning process to form the openings OP2. The patterning process includes photolithography and one or more etching processes, for example. In some embodiments, the openings OP2 penetrate through the etch stop layer ES2. Meanwhile, the openings OP2 do not penetrate through the semiconductor substrate 110. In some embodiments, the openings OP2 may be referred to as recesses in the semiconductor substrate 110.

Referring to FIG. 4C, the capacitor 1300 is formed in the openings OP2 and on the etch stop layer ES2. In some embodiments, the capacitor structure 1300 includes an electrode 1302, a storage layer 1304, an electrode 1306, a storage layer 1308, an electrode 1310, and a storage layer 1312. In some embodiments, the capacitor structure 1300 is formed by the following steps. First, a first electrode material layer (not shown) is conformally formed on the etch stop layer ES2 and the semiconductor substrate 110 by a suitable technique such as a PVD process or a plating process. That is, a portion of the first electrode material layer is disposed on the top surface of the etch stop layer ES2 while another portion of the first electrode material layer extends into the openings OP2. Thereafter, a first storage material layer (not shown) is conformally formed on the first electrode material layer. In some embodiments, the first storage material layer is formed by, for example, CVD, PECVD, FCVD, HDP-CVD, SACVD, PVD, or ALD. In some embodiments, a portion of the first storage material layer is disposed over the etch stop layer ES2 while another portion of the first storage material layer extends into the openings OP2. Subsequently, a second electrode material layer (not shown) is conformally formed on the first storage material layer by a suitable technique such as a PVD process or a plating process. In some embodiments, a portion of the second electrode material layer is disposed over the etch stop layer ES2 while another portion of the second electrode material layer extends into the openings OP2. Then, a second storage material layer (not shown) is conformally formed on the second electrode material layer. In some embodiments, the second storage material layer is formed by, for example, CVD, PECVD, FCVD, HDP-CVD, SACVD, PVD, or ALD. In some embodiments, a portion of the second storage material layer is disposed over the etch stop layer ES2 while another portion of the second storage material layer extends into the openings OP2. Thereafter, a third electrode material layer (not shown) is conformally formed on the second storage material layer by a suitable technique such as a PVD process or a plating process. In some embodiments, a portion of the third electrode material layer is disposed over the etch stop layer ES2 while another portion of the third electrode material layer extends into the openings OP2. After the third electrode material layer is deposited, a third storage material layer (not shown) is conformally formed on the third electrode material layer. In some embodiments, the third storage material layer is formed by, for example, CVD, PECVD, FCVD, HDP-CVD, SACVD, PVD, or ALD. In some embodiments, a portion of the third storage material layer is disposed over the etch stop layer ES2 while another portion of the third storage material layer extends into the openings OP2. Lastly, the first electrode material layer, the first storage material layer, the second electrode material layer, the second storage material layer, the third electrode material layer, and the third storage material layer are patterned by a photolithography and etching process to respectively form the electrode 1302, the storage layer 1304, the electrode 1306, the storage layer 1308, the electrode 1310, and the storage layer 1312. In some embodiments, the electrode 1302 and the storage layer 1304 are patterned using the same photomask. Meanwhile, the electrode 1306 and the storage layer 1308 are patterned using another photomask. Moreover, the electrode 1310 and the storage layer 1312 are patterned using yet another photomask. As such, sidewalls of tails of the electrode 1302 are aligned with sidewalls of tails of the storage layer 1304, sidewalls of tails of the electrode 1306 are aligned with sidewalls of tails of the storage layer 1308, and sidewalls of tails of the electrode 1310 are aligned with sidewalls of tails of the storage layer 1312, as shown in FIG. 4C. Meanwhile, the sidewalls of the tails of the electrode 1306 are not aligned with the sidewalls of the tails of the electrode 1302 and the sidewalls of the tails of the electrode 1310. For example, the electrode 1306 exposes a portion of a top surface of the storage layer 1304, and the electrode 1310 exposes a portion of a top surface of the storage layer 1308.

In some embodiments, the electrodes 1302, 1306, and 1310 respectively include various conductive materials, such as a metal, a metal alloy, a metal nitride, a metal silicide, a metal oxide, graphene, or a combination thereof. For example, the electrodes 1302, 1306, and 1310 may respectively include Al, Ti, Cu, W, Pt, Pd, Os, Ru, Ta, or an alloy thereof, TiN, TaN, WN, MoN, TaSiN, TiSiN, WSiN, tungsten silicide, titanium silicide, cobalt silicide, zirconium silicide, platinum silicide, molybdenum silicide, copper silicide, nickel silicide, ITO, IrO₂, ReO₂, ReO₃, or a combination thereof. In some embodiments, the storage layers 1304, 1308, and 1312 respectively include a high-k dielectric material having a dielectric constant greater than 4, greater than 7, or even greater than 10. The high-k dielectric material may include HfO₂, HfSiO₄, HfSiON, Al₂O₃, Y₂O₃, La₂O₃, LaAlO, Ta₂O₅, TiO₂, ZrO₂, ZrSiO₄, HfZrO, SrBi₂Ta₂O₉ (SBT), or a combination thereof.

As illustrated in FIG. 4C, the capacitor structure 1300 is partially located in the openings OP2. Therefore, the capacitor structure 1300 may be referred to as a deep trench capacitor (DTC). As illustrated in FIG. 4C, the electrode 1306 is disposed over the electrode 1302, and the storage layer 1304 is between the electrode 1302 and the electrode 1306. For example, the storage layer 1304 is in physical contact with both the electrode 1302 and the electrode 1306 to form a MIM structure. Meanwhile, the electrode 1310 is disposed over the electrode 1306, and the storage layer 1308 is between the electrode 1306 and the electrode 1310. For example, the storage layer 1308 is in physical contact with both the electrode 1306 and the electrode 1310 to form another MIM structure. That is, the capacitor structure 1300 may be referred to as a MIM capacitor. In some embodiments, the storage layers 1304 and 1308 are utilized to store capacitance.

Referring to FIG. 4D, after the capacitor structure 1300 is formed, the protection layer PL is formed on the etch stop layer ES2 and the capacitor structure 1300. In some embodiments, the protection layer PL includes a molding compound, a molding underfill, or the like. Alternatively, the protection layer PL may be made of a polymeric material, such as polyimide, epoxy resin, acrylic resin, phenol resin, BCB, PBO, or other suitable polymer-based dielectric materials. In some embodiments, the protection layer PL may include fillers. Alternatively, the protection layer PL may be free of fillers. In some embodiments, the protection layer PL is formed by the following steps. First, a protection material layer (not shown) is formed on the etch stop layer ES2 and the capacitor structure 1300. Subsequently, a grinding or thinning process is performed on the protection material layer until the TSV 140 is revealed. The thinning process includes, for example, a mechanical grinding process, a CMP process, or the like. As illustrated in FIG. 4D, the protection layer PL covers the capacitor structure 1300. The protection layer PL also extends into the openings OP2. That is, a portion of the electrode 1302, a portion of the storage layer 1304, a portion of the electrode 1306, a portion of the storage layer 1308, a portion of the electrode 1310, a portion of the storage layer 1312, and a portion of the protection layer PL fill up the openings OP2. In some embodiments, the capacitor structure 1300 is sandwiched between the semiconductor substrate 110 and the protection layer PL. In addition, the capacitor structure 1300 is also sandwiched between the etch stop layer ES2 and the protection layer PL. In some embodiments, the protection layer PL laterally surrounds the TSV 140. As illustrated in FIG. 4D, the protruding portion of the TSV 140 is laterally encapsulated by the protection layer PL.

Referring to FIG. 4E, a plurality of conductive vias V1 is formed in the protection layer PL. In some embodiments, a material of the conductive vias V1 include aluminum, titanium, copper, nickel, tungsten, or alloys thereof. The conductive vias V1 may be formed by, for example, electroplating, deposition, and/or photolithography and etching. In some embodiments, the conductive vias V1 penetrate through the protection layer PL. Moreover, some of the conductive vias V1 further penetrate through the corresponding storage layers 1304, 1308, and 1312 to be in physical contact with the corresponding electrodes 1302, 1306, and 1310. For example, one of the conductive vias V1 penetrate through the protection layer PL and the storage layer 1304 to be in physical contact with the electrode 1302. Meanwhile, another one of the conductive vias V1 penetrate through the protection layer PL and the storage layer 1308 to be in physical contact with the electrode 1306. Moreover, yet another one of the conductive vias V1 penetrate through the protection layer PL and the storage layer 1312 to be in physical contact with the electrode 1310. In some embodiments, some of the conductive vias V1 penetrate through the protection layer PL and the etch stop layer ES2 to be in physical contact with the semiconductor substrate 110.

Referring to FIG. 4F, an etch stop layer ES3 is formed on the protection layer PL, the conductive vias V1, and the TSV 140. In some embodiments, a material of the etch stop layer ES3 includes silicon carbide, silicon nitride, or the like. In some embodiments, the etch stop layer ES3 is formed by any suitable method, such as CVD, spin-on coating, or the like.

Referring to FIG. 4G, the conductive patterns 702 (i.e., the bottommost conductive patterns 702 in FIG. 3B) and the dielectric layer 704 (i.e., the bottommost dielectric layer 704 in FIG. 3B) are formed on the etch stop layer ES2, the protection layer PL, the conductive vias V1, and the TSV 140. In some embodiments, the conductive patterns 702 penetrate through the dielectric layer 704 and the etch stop layer ES3 to be in physical contact with the underlying conductive vias V1 or the underlying TSV 140. Therefore, the capacitor structure 1300 and the TSV 140 are electrically connected to the conductive patterns 702. That is, the capacitor structure 130 is electrically connected to the redistribution structure 700. For example, the electrodes 1302, 1306, and 1310 are respectively electrically connected to different conductive patterns 702 of the redistribution structure 700.

Referring back to FIG. 3B, after the redistribution structure 700 is formed, the conductive pads 900 are formed on the redistribution structure 700. In some embodiments, a material of the conductive pads 900 includes aluminum, titanium, copper, nickel, tungsten, or alloys thereof. In some embodiments, the material of the conductive pads 900 is different from the material of the conductive patterns 702 of the redistribution structure 700. For example, the conductive patterns 702 of the redistribution structure 700 may be made of copper while the conductive pads 900 may be made of aluminum. However, the disclosure is not limited thereto. In some alternative embodiments, the material of the conductive pads 900 may be the same as the material of the conductive patterns 702 of the redistribution structure 700. In some embodiments, the conductive pads 900 may be formed by, for example, electroplating, deposition, and/or photolithography and etching. As illustrated in FIG. 3B, the conductive pads 900 are directly in contact with the conductive vias 706, thereby rendering electrical connection with the redistribution structure 700. In some embodiments, the conductive pads 900 are used to establish electrical connection with other components (not shown) subsequently formed or provided. In some alternative embodiments, the conductive pads 900 may be test pads.

In some embodiments, after the conductive pads 900 are formed, the passivation layer 1000 is formed on the redistribution structure 700 and the conductive pads 900 to partially cover the conductive pads 900. In some embodiments, a material of the passivation layer 1000 includes oxides, such as silicon oxide or the like. Alternatively, the passivation layer 1000 may include polyimide, epoxy resin, acrylic resin, phenol resin, BCB, PBO, or any other suitable polymer-based dielectric material. The passivation layer 1000, for example, may be formed by suitable fabrication techniques, such as spin-on coating, CVD, PECVD, or the like. In some embodiments, the passivation layer 1000 is formed to expose at least a portion of each conductive pad 900.

Thereafter, the UBM patterns 1100 are formed over the conductive pads 900 and the passivation layer 1000. In some embodiments, the UBM patterns 1100 are in direct contact with the portion of the conductive pads 900 exposed by the passivation layer 1000. That is, the UBM patterns 1100 are electrically connected to the conductive pads 900 and the redistribution structure 700. In some embodiments, a material of the UBM patterns 1100 includes aluminum, titanium, copper, nickel, tungsten, or alloys thereof. The UBM patterns 1100 may be formed by, for example, electroplating, deposition, and/or photolithography and etching.

Referring to FIG. 3C, a plurality of conductive terminals 1200 is formed on the UBM patterns 1100. In some embodiments, the conductive terminals 1200 are attached to the UBM patterns 1100 through a solder flux. In some embodiments, the conductive terminals 1200 are, for example, solder balls, BGA balls, or C4 bumps. In some embodiments, the conductive terminals 1200 are made of a conductive material with low resistivity, such as Sn, Pb, Ag, Cu, Ni, Bi, or an alloy thereof. As illustrated in FIG. 3C, the capacitor structure 1300 is between the die 100 and the conductive terminals 1200.

After the conductive terminals 1200 are formed, a singulation process is performed to form a plurality of integrated circuits 20. In some embodiments, the dicing process or the singulation process typically involves dicing with a rotating blade or a laser beam. In other words, the dicing or singulation process is, for example, a laser cutting process, a mechanical cutting process, or other suitable processes. In some embodiments, the die 100 is stacked on and bonded to the die 400. In other words, multiple dies 100 and 400 are integrated into a single integrated circuit 20. As such, the integrated circuit 20 may be referred to as a “system on integrated circuit (SOIC) chip.”

As illustrated in FIG. 3C, the capacitor structure 1300 is integrated into the semiconductor substrate 110 and the protection layer PL of the integrated circuit 20. Since the location of the capacitor structure 1300 is close to a power source, the phenomena of IR drop may be sufficiently reduced, thereby rendering higher operation performance and lower power consumption. In addition, with the integration of the capacitor structure 1300 into the semiconductor substrate 110 and the protection layer PL, the existence of the capacitor structure 200 and the capacitor structure 500 may be optional, thereby releasing/free up routing area in the interconnect structures 130 and 430 of the dies 100 and 400. As such, the circuit designs in the dies 100 and 400 may be more flexible, and the overall size of the dies 100 and 400 may be reduced. Moreover, since the integration of the capacitor structure 1300 into the semiconductor substrate 110 and the protection layer PL is compatible with the existing process, the manufacturing complexity of the integrated circuit 20 may be sufficiently simplified.

In accordance with some embodiments of the disclosure, an integrated circuit includes a carrier, a first die, a second die, a redistribution structure, and a first capacitor structure. The first die is disposed on the carrier. The second die is disposed on and bonded to the first die. The redistribution structure is disposed on the second die. The first die and the redistribution structure are located on two opposite sides of the second die. The first capacitor structure is embedded in the redistribution structure.

In accordance with some embodiments of the disclosure, an integrated circuit includes a first die, a second die, a redistribution structure, a protection layer, and a first capacitor structure. The second die is disposed on and bonded to the first die. The redistribution structure is disposed over the second die. The protection layer is sandwiched between the second die and the redistribution structure. The first capacitor structure is partially embedded in the protection layer.

In accordance with some embodiments of the disclosure, a manufacturing method of an integrated circuit includes at least the following steps. A first die is provided. A second die is bonded to the first die. A protection layer is deposited on the first die opposite to the second die. A redistribution structure is formed on the protection layer. Conductive terminals are formed over the redistribution structure. A first capacitor structure is formed between the first die and the conductive terminals.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A integrated circuit, comprising:
a carrier;
a first die disposed on the carrier;
a second die disposed on and bonded to the first die;
a redistribution structure disposed on the second die, wherein the first die and the redistribution structure are located on two opposite sides of the second die; and
a first capacitor structure embedded in the redistribution structure.

2. The integrated circuit of claim 1, wherein the first capacitor structure comprises:
a first electrode;
a second electrode disposed over the first electrode;
a first storage layer between the first electrode and the second electrode;
a third electrode disposed over the second electrode; and
a second storage layer between the second electrode and the third electrode.

3. The integrated circuit of claim 2, wherein the redistribution structure comprises:
dielectric layers;
conductive patterns embedded in the dielectric layers; and
conductive vias connecting conductive patterns located at different level heights, wherein the first electrode, the first storage layer, the second electrode, the second storage layer, and the third electrode are in physical contact with sidewalls of the conductive vias.

4. The integrated circuit of claim 1, further comprising:
a first bonding layer located between the first die and the second die; and
a second bonding layer located between the first bonding layer and the second die.

5. The integrated circuit of claim 4, wherein the first die comprises:
a first semiconductor substrate;
a first interconnect structure disposed on the first semiconductor substrate;
first conductive pads disposed over the first interconnect structure;
a first passivation layer disposed on the first interconnect structure and the first conductive pads; and
first bonding vias electrically connecting the first bonding layer with the first interconnect structure.

6. The integrated circuit of claim 5, further comprising a second capacitor structure embedded in the first interconnect structure.

7. The integrated circuit of claim 5, wherein the second die comprises:
a second semiconductor substrate;
a second interconnect structure disposed on the second semiconductor substrate;
through semiconductor vias (TSV) embedded in the second semiconductor substrate and the second interconnect structure;
second conductive pads disposed over the second interconnect structure;
a second passivation layer disposed on the second interconnect structure and the second conductive pads; and
second bonding vias electrically connecting the second bonding layer with the second interconnect structure.

8. The integrated circuit of claim 7, further comprising a third capacitor structure embedded in the second interconnect structure.

9. A integrated circuit, comprising:
a first die;
a second die disposed on and bonded to the first die;
a redistribution structure disposed over the second die;
a protection layer sandwiched between the second die and the redistribution structure; and
a first capacitor structure partially embedded in the protection layer.

10. The integrated circuit of claim 9, wherein the second die comprises a first semiconductor substrate, the protection layer is sandwiched between the semiconductor substrate and the redistribution structure, and the first capacitor structure is further partially embedded in the first semiconductor substrate.

11. The integrated circuit of claim 9, wherein the first capacitor structure comprises:
a first electrode;
a second electrode disposed over the first electrode;
a first storage layer between the first electrode and the second electrode;
a third electrode disposed over the second electrode;
a second storage layer between the second electrode and the third electrode; and
a third storage layer disposed on the third electrode.

12. The integrated circuit of claim 11, wherein sidewalls of tails of the first electrode are aligned with sidewalls of tails of the first storage layer, sidewalls of tails of the second electrode are aligned with sidewalls of tails of the second storage layer, and sidewalls of tails of the third electrode are aligned with sidewalls of tails of the third storage layer.

13. The integrated circuit of claim 11, wherein the first semiconductor substrate comprises openings, and a portion of the first electrode, a portion of the first storage layer, a portion of the second electrode, a portion of the second storage layer, a portion of the third electrode, a portion the third storage layer, and a portion of the protection layer fill up the openings.

14. The integrated circuit of claim 9, wherein
the first die comprises:
a first semiconductor substrate; and
a first interconnect structure disposed on the first semiconductor substrate, and the integrated circuit further comprises:
a second capacitor structure embedded in the first interconnect structure.

15. The integrated circuit of claim 14, wherein
the second die comprises:
a second semiconductor substrate; and
a second interconnect structure disposed on the second semiconductor substrate, and
the integrated circuit further comprises:
a third capacitor structure embedded in the second interconnect structure.

16. A manufacturing method of an integrated circuit, comprising:
providing a first die;
bonding a second die to the first die;
depositing a protection layer on the first die opposite to the second die;
forming a redistribution structure on the protection layer;
forming conductive terminals over the redistribution structure; and
forming a first capacitor structure between the first die and the conductive terminals.

17. The method of claim 16, wherein the first capacitor is formed to be embedded in the redistribution structure.

18. The method of claim 16, wherein the first capacitor is formed to be partially embedded in the protection layer.

19. The method of claim 16, further comprising:
forming a second capacitor structure in a first interconnect structure of the first die; and
forming a third capacitor structure in a second interconnect structure of the second die.

20. The method of claim 16, wherein forming the first capacitor comprises:
providing a first electrode;
forming a first storage layer on the first electrode;
deposing a second electrode on the first storage layer;
forming a second storage layer on the second electrode; and
depositing a third electrode on the second storage layer.
